(19) United States
(12) Patent Application Publication
(10) Pub. No.: US 2026/0068147 A1
(43) Pub. Date: Mar. 5, 2026

(54) SEMICONDUCTOR MEMORY DEVICE

(71) Applicant: SAMSUNG ELECTRONICS CO., LTD., Suwon-si (KR)

(72) Inventors: Jongkwan JUNG, Suwon-si (KR); Seongjin JEONG, Suwon-si (KR); Jongmin LEE, Suwon-si (KR); Minseung SONG, Suwon-si (KR); Seungmi LEE, Suwon-si (KR); Suneum JUNG, Suwon-si (KR)

(73) Assignee: SAMSUNG ELECTRONICS CO., LTD., Suwon-si (KR)

(21) Appl. No.: 19/299,903

(22) Filed: Aug. 14, 2025

(30) Foreign Application Priority Data
Aug. 27, 2024 (KR) 10-2024-0115165

(51) Int. Cl. H10B 12/00

(52) U.S. Cl. CPC H10B 12/50; H10B 12/09; H10B 12/315

(57) ABSTRACT

A semiconductor memory device includes: a plurality of landing pads connected to active regions in the memory cell region; an etch stop layer including an internal stop layer having a first thickness and a peripheral stop layer having a second thickness greater than the first thickness, wherein the etch stop layer is provided on the memory cell region and a peripheral region; lower electrodes penetrating the etch stop layer and connected to the landing pads; a capacitor dielectric layer covering the lower electrodes; and an upper electrode covering the capacitor dielectric layer. A first group of the lower electrodes penetrate the peripheral stop layer, and a second group of the lower electrodes penetrate the internal stop layer and are connected to the landing pads.

### CROSS-REFERENCE TO RELATED APPLICATION

This application claims priority to Korean Patent Application No. 10-2024-0115165, filed on Aug. 27, 2024, in the Korean Intellectual Property Office, the disclosure of which is incorporated by reference herein in its entirety.

### BACKGROUND

The present disclosure relates to a semiconductor memory device, and more particularly, to a semiconductor memory device having a capacitor structure.

With the rapid development of the electronics industry and the demand of users, electronic devices have become increasingly smaller and lighter. Accordingly, high integration is required for semiconductor memory devices used in electronic devices, and design rules for the components of semiconductor memory devices have been reduced. Accordingly, the aspect ratio of the capacitor structure increases, making it difficult to secure the reliability of semiconductor memory devices.

### SUMMARY

One or more embodiments provide a semiconductor memory device having a capacitor structure capable of ensuring reliability.

According to an aspect of an embodiment, a semiconductor memory device includes: a substrate in which a plurality of active regions are defined by a device isolation film in a memory cell region and a logic active region is defined by a logic device isolation film in a peripheral region; a plurality of landing pads connected to the plurality of active regions in the memory cell region, on the substrate; an etch stop layer including an internal stop layer having a first thickness and a peripheral stop layer having a second thickness greater than the first thickness, wherein the etch stop layer is provided on the memory cell region and the peripheral region; a plurality of lower electrodes penetrating the etch stop layer and connected to the plurality of landing pads; a capacitor dielectric layer covering the plurality of lower electrodes; and an upper electrode covering the capacitor dielectric layer. A first group of the plurality of lower electrodes penetrate the peripheral stop layer, and a second group of the plurality of lower electrodes penetrate the internal stop layer and are connected to the plurality of landing pads.

According to another aspect of an embodiment, a semiconductor memory device includes: a substrate in which a plurality of active regions are defined by a device isolation film in a memory cell region and a plurality of logic active regions are defined by a logic device isolation film in a peripheral region; a plurality of word lines extending in a first horizontal direction across the plurality of active regions in the memory cell region; a plurality of bit lines on the plurality of active regions and extending in a second horizontal direction orthogonal to the first horizontal direction; a plurality of buried contacts filling a lower portion of a space between the plurality of bit lines and connected to the plurality of active regions; a plurality of landing pads filling an upper portion of the space between the plurality of bit lines, extending over the plurality of bit lines, and separated from each other by a filling insulating layer; a gate line on the plurality of logic active regions; a plurality of logic bit lines on the gate line; an etch stop layer including an internal stop layer having a first thickness and a peripheral stop layer having a second thickness greater than the first thickness, wherein the etch stop layer is provided on the memory cell region and the peripheral region, and wherein the etch stop layer overlaps the plurality of landing pads and the plurality of logic bit lines; a plurality of lower electrodes including a plurality of real lower electrodes and a plurality of dummy lower electrodes provided around the plurality of real lower electrodes, wherein the plurality of lower electrodes penetrate the etch stop layer and are connected to the plurality of landing pads; a capacitor dielectric layer covering the plurality of lower electrodes; and an upper electrode covering the capacitor dielectric layer. A first group of the plurality of dummy lower electrodes penetrate the internal stop layer, and a second group of the plurality of dummy lower electrodes penetrate the peripheral stop layer.

According to another aspect of an embodiment, a semiconductor memory device includes: a substrate in which a plurality of active regions are defined by a device isolation film in a memory cell region and a plurality of logic active regions are defined by a logic device isolation film in a peripheral region; a gate line on the plurality of logic active regions; a logic bit line on the gate line; a plurality of word lines extending in a first horizontal direction across the plurality of active regions; a plurality of bit lines on the plurality of active regions and extending in a second horizontal direction orthogonal to the first horizontal direction; a plurality of buried contacts filling a lower portion of a space between the plurality of bit lines and connected to the plurality of active regions; a plurality of landing pads extending over the plurality of bit lines, while filling an upper portion of the space between the plurality of bit lines, at least some separated from each other by a filling insulating layer being positioned at a vertical level corresponding to a vertical level of the logic bit line; an etch stop layer covering the memory cell region and the peripheral region, wherein the etch stop layer overlaps the plurality of landing pads, the filling insulating layer, and the plurality of bit lines; a plurality of lower electrodes including a plurality of real lower electrodes and a plurality of dummy lower electrodes provided around the plurality of real lower electrodes, wherein the plurality of lower electrodes penetrate the etch stop layer and are connected to the plurality of landing pads; a capacitor dielectric layer covering the plurality of lower electrodes; an upper electrode covering the capacitor dielectric layer; a cover insulating layer covering the etch stop layer and the upper electrode; a plurality of interconnection lines on the filling insulating layer; a first interconnection contact plug penetrating the filling insulating layer and connecting one of the plurality of interconnection lines to the upper electrode; and a second interconnection contact plug penetrating the filling insulating layer and connecting another one of the plurality of interconnection lines to the logic bit line. The etch stop layer includes an internal stop layer having a first thickness and a peripheral stop layer having a second thickness greater than the first thickness. A first group of the plurality of dummy lower electrodes and all of the plurality of real lower electrodes penetrate the internal stop layer, and a second group of the plurality of dummy lower electrodes penetrate the peripheral stop layer.

### BRIEF DESCRIPTION OF DRAWINGS

The above and other aspects will be more apparent from the following description of example embodiments taken in conjunction with the accompanying drawings, in which:

FIG. 1 is a block diagram illustrating a semiconductor memory device according to embodiments;

FIG. 2 is a schematic planar layout illustrating a semiconductor memory device according to embodiments;

FIGS. 3A, 3B, 3C, 3D, 4A, 4B, 4C, 4D, 5A, 5B, 5C, 5D, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C and 16D are cross-sectional views illustrating a method of manufacturing a semiconductor memory device, according to embodiments;

FIGS. 17A, 17B, 17C and 17D are cross-sectional views illustrating a semiconductor memory device according to embodiments;

FIG. 18 is a schematic planar layout diagram of main components included in a semiconductor memory device according to embodiments;

FIGS. 19 to 21 are cross-sectional views illustrating a method of manufacturing a semiconductor memory device, according to embodiments; and

FIG. 22 is a cross-sectional view illustrating a semiconductor memory device according to embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

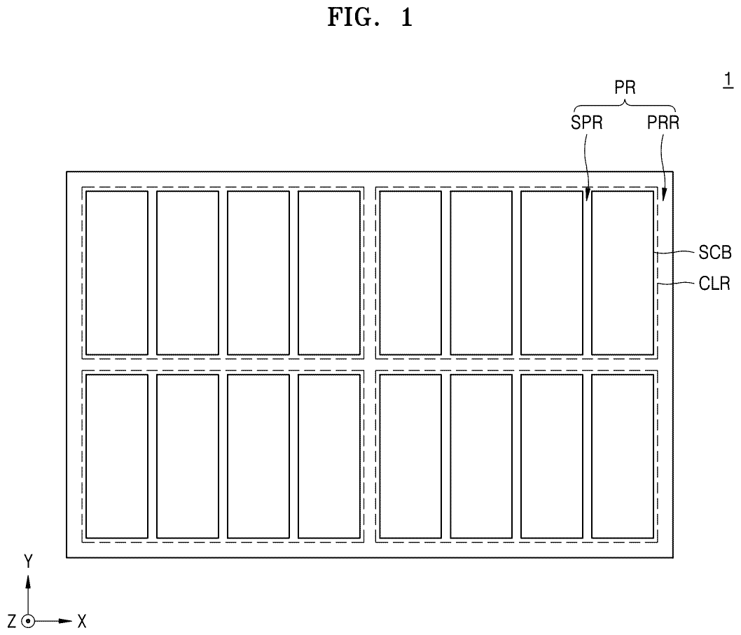

FIG. 1 is a block diagram illustrating a semiconductor memory device 1 according to embodiments.

Referring to FIG. 1, the semiconductor memory device 1 may include a cell region CLR in which memory cells are arranged and a main peripheral region PRR surrounding the cell region CLR.

According to an embodiment, the cell region CLR may include cell blocks SCB and sub-peripheral regions SPR that the separate cell blocks SCB from each other. A plurality of memory cells may be arranged in the cell blocks SCB. A cell block SCB refers to an region in which the memory cells are arranged regularly with uniform spacing, and the cell block SCB may be referred to as a sub-cell block.

Logic cells for inputting/outputting electrical signals to/from the memory cells may be arranged in the main peripheral region PRR and sub-peripheral region SPR. In some embodiments, the main peripheral region PRR may be referred to as a peripheral circuit region, and the sub-peripheral region SPR may be referred to as a core circuit region. A peripheral region PR may include a main peripheral region PRR and sub-peripheral regions SPR. That is, the peripheral region PR may be a core and peripheral circuit region including a peripheral circuit region and a core circuit region. In some embodiments, at least a portion of the sub-peripheral region SPR may be provided solely as space for separating the cell blocks SCB.

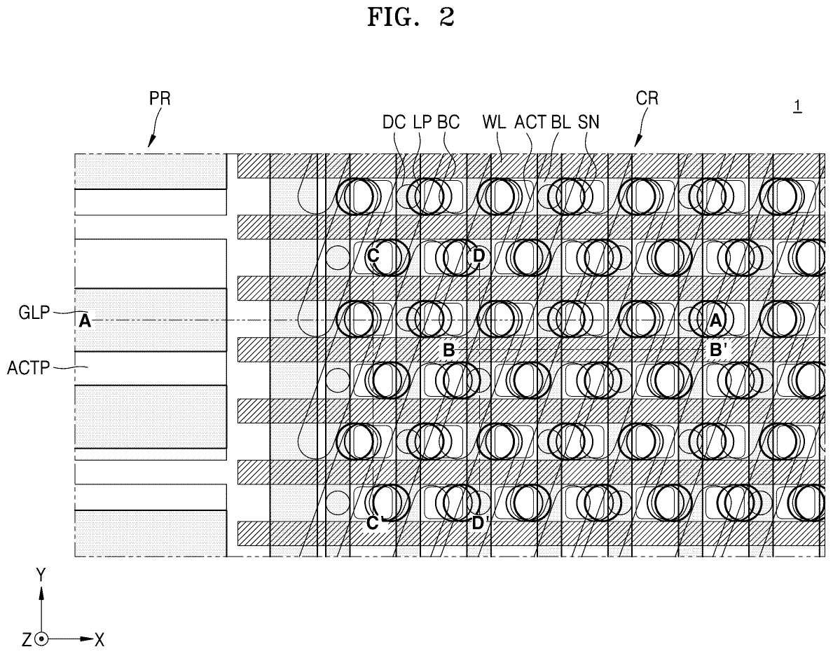

FIG. 2 is a schematic planar layout illustrating the semiconductor memory device 1 according to embodiments.

Referring to FIG. 2, the semiconductor memory device 1 includes a memory cell region CR and a peripheral region PR. The semiconductor memory device 1 may include a plurality of active regions ACT formed in the memory cell region CR and a plurality of logic active regions ACTP formed in the peripheral region PR. The memory cell region CR may be a cell block SCB in which a plurality of memory cells are arranged as shown in FIG. 1, and the peripheral region PR may be a peripheral region PR including the main peripheral region PRR and the sub-peripheral region SPR as shown in FIG. 1.

The active regions ACT arranged in the memory cell region CR may be arranged to have a longer axis in a diagonal direction with respect to a first horizontal direction (an X direction) and a second horizontal direction (a Y direction) orthogonal to the first horizontal direction (the X direction). In some embodiments, the active regions ACT may be arranged in rows diagonally with respect to the first horizontal direction (the X direction) and the second horizontal direction (the Y direction) and may be arranged in rows in the second horizontal direction (the Y direction).

A plurality of word lines WL may extend parallel to each other in the first horizontal direction (the X direction) across the active regions ACT in the memory cell region CR. In some embodiments, a pair of word lines WL may extend parallel to each other in the first horizontal direction (the X direction) in one active region ACT. A plurality of bit lines BL may extend parallel to each other in the second horizontal direction (the Y direction) intersecting the first horizontal direction (the X direction) over the word lines WL. In some embodiments, one bit line BL may extend in the second horizontal direction (the Y direction) in one active region ACT. The bit lines BL may be respectively connected to the active regions ACT via a plurality of direct contacts DC. The direct contacts DC may be located at the intersections of the bit lines BL and the active regions ACT.

In some embodiments, a plurality of buried contacts BC may be formed between two adjacent bit lines BL among the bit lines BL. In some embodiments, the buried contacts BC may be arranged in a row in each of the first horizontal direction (the X direction) and the second horizontal direction (the Y direction). In some embodiments, a pair of buried contacts BC may be connected to one active region ACT. For example, one buried contact BC may be connected to each of both end portions of one active region ACT.

A plurality of landing pads LP may be respectively formed on the buried contacts BC. The landing pads LP may be arranged to at least partially overlap the buried contacts BC. In some embodiments, the landing pads LP may each extend to an upper portion of one of two adjacent bit lines BL.

A plurality of storage nodes SN may be respectively formed on the landing pads LP. The storage nodes SN may be formed on top of the bit lines BL. The storage nodes SN may be lower electrodes of multiple capacitors, respectively. The storage node SN may be connected to the active region ACT via the landing pad LP and the buried contact BC.

A plurality of gate lines GLP may be arranged on the logic active region ACTP in the peripheral region PR. In FIG. 2, a plurality of gate lines GLP are illustrated as extending parallel to each other in the first horizontal direction (the X direction) on the logic active region ACTP and having a generally constant width in the second horizontal direction (the Y direction), but embodiments are not limited thereto. For example, each of the gate lines GLP may have different widths or may vary in width and may have curves or extend in different directions.

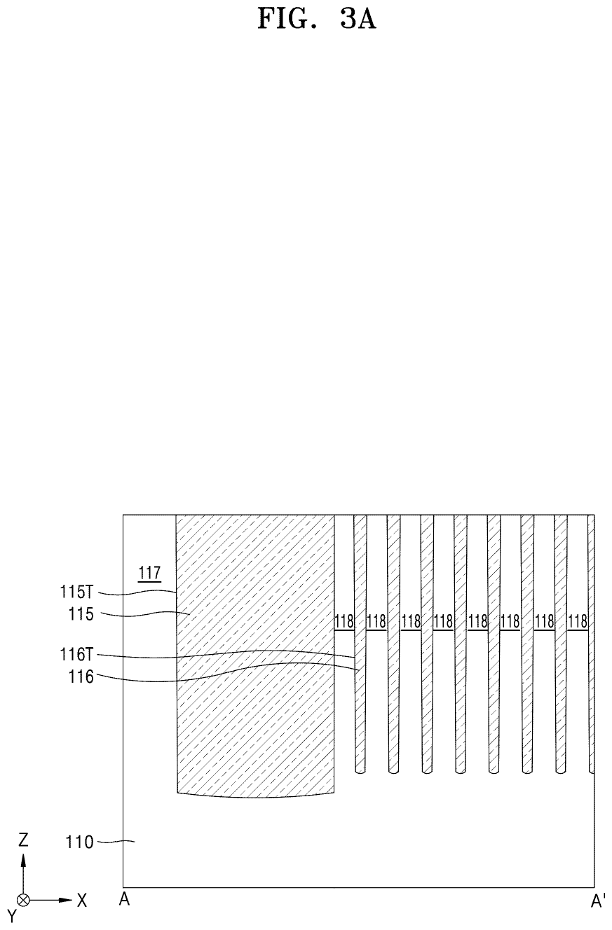

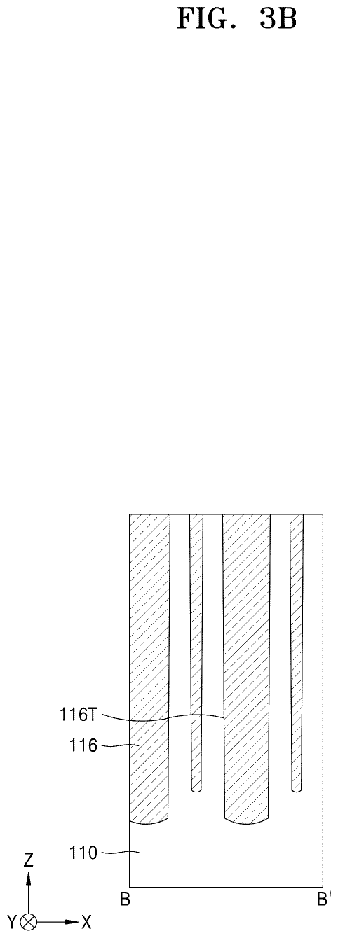

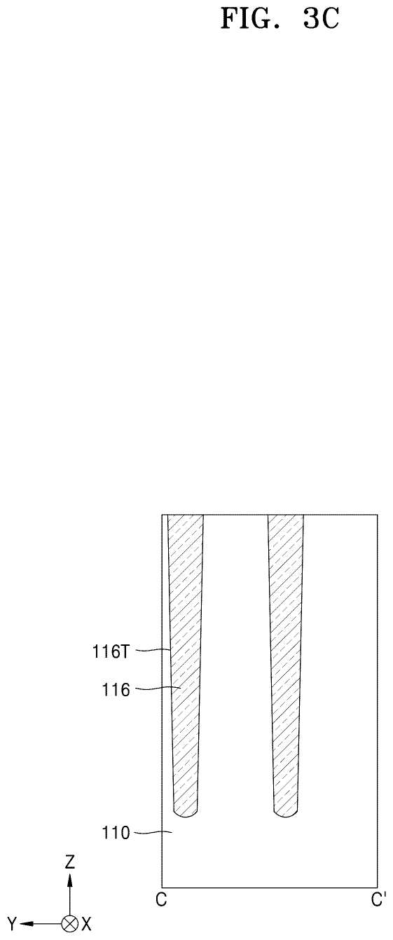

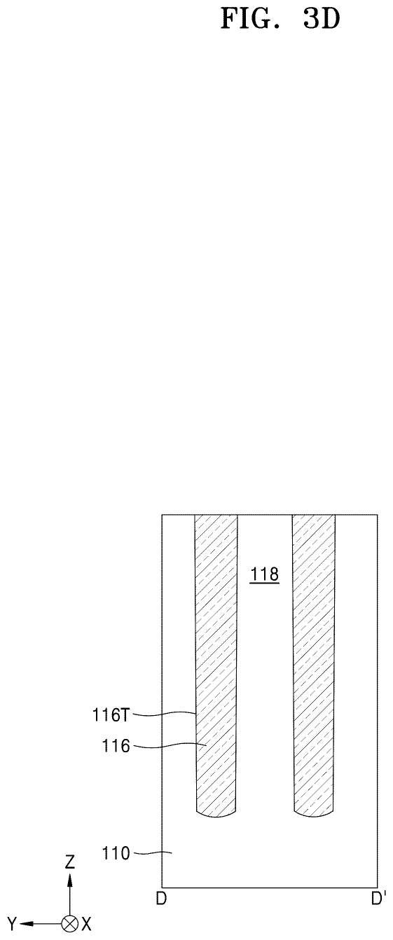

In FIG. 2, other components except for a plurality of logic active regions ACTP and a plurality of gate lines GLP in the peripheral region PR are omitted for convenience of illustration. In addition, although FIG. 2 illustrates that the gate lines GLP are arranged only on the logic active regions ACTP, embodiments are not limited thereto. For example, at least some of the gate lines GLP may extend outside the logic active region ACTP, i.e., onto a logic device isolation film (115 in FIG. 3A).

The gate lines GLP may be formed at the same level as the bit lines BL. In some embodiments, the gate lines GLP and the bit lines BL may be formed of the same material or at least partially formed of the same material. For example, all or part of the process of forming all or some of the gate lines GLP and all or part of the process of forming the bit lines BL may be the same process.

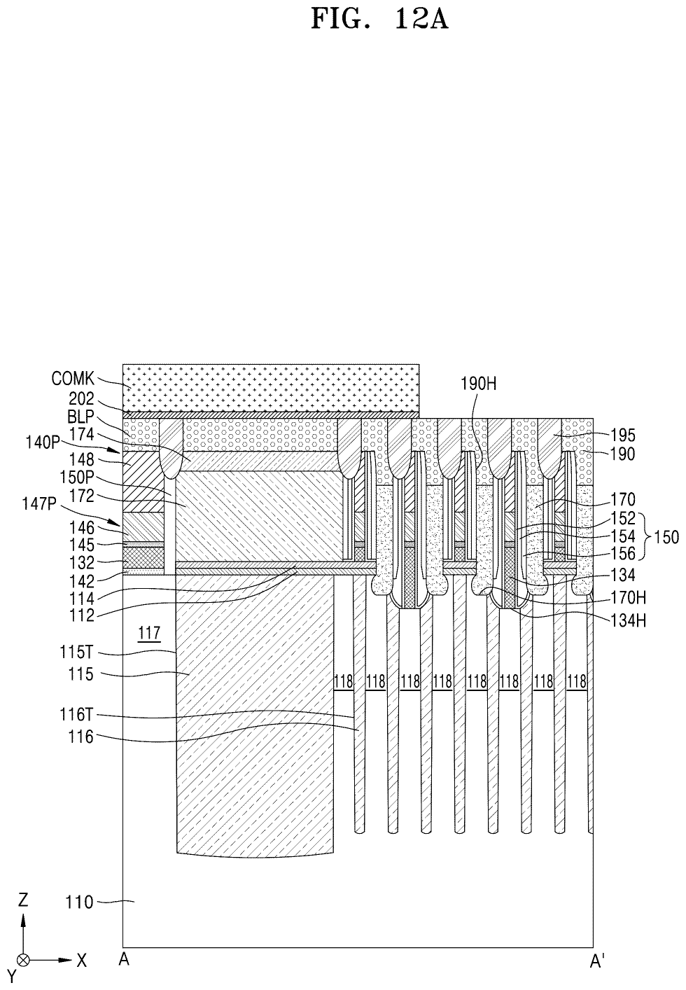

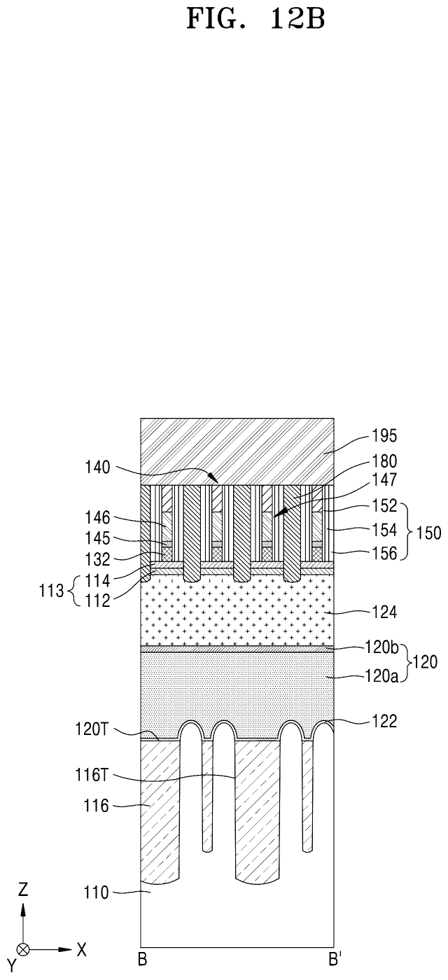

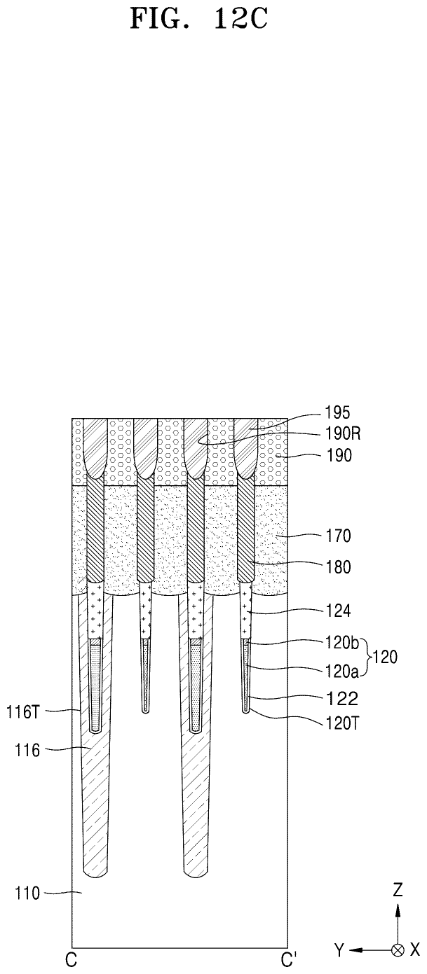

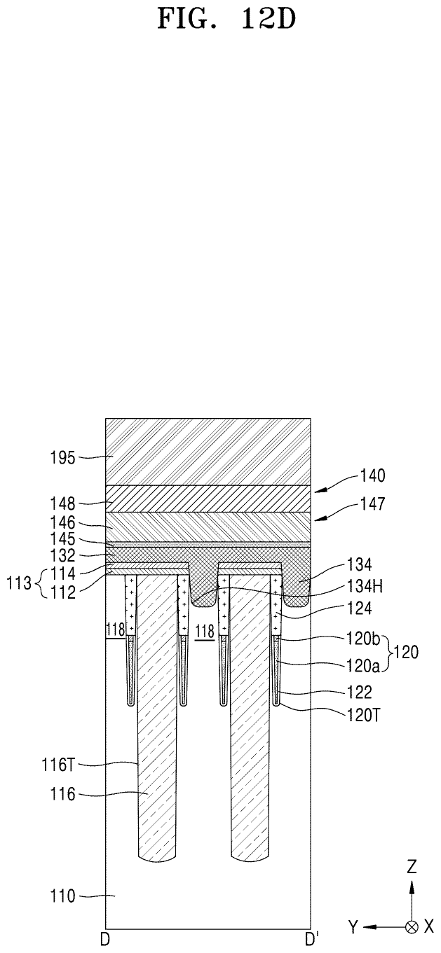

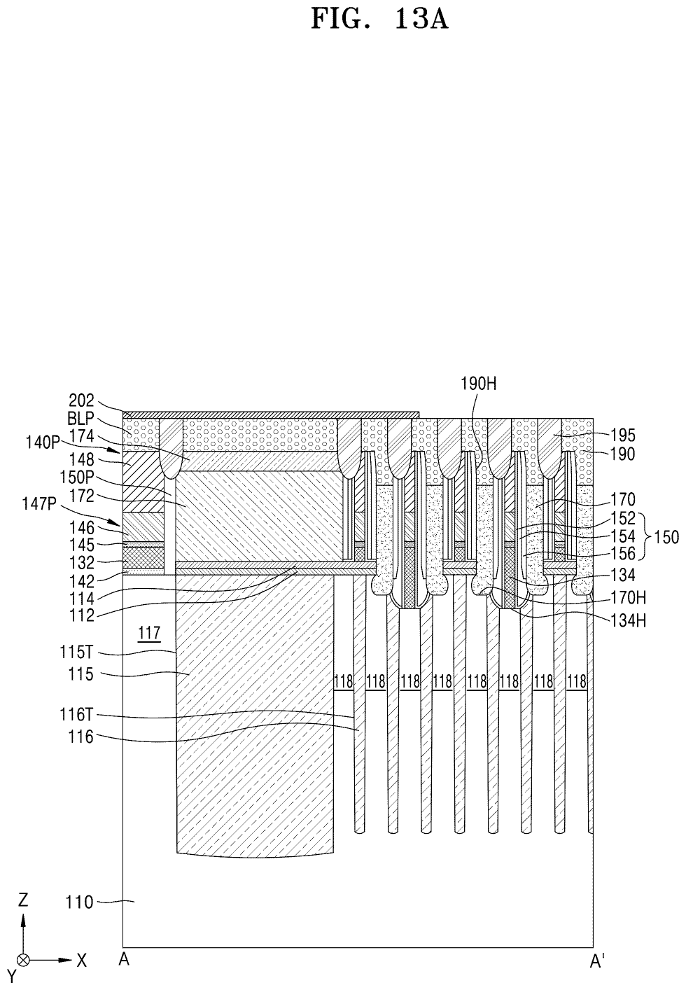

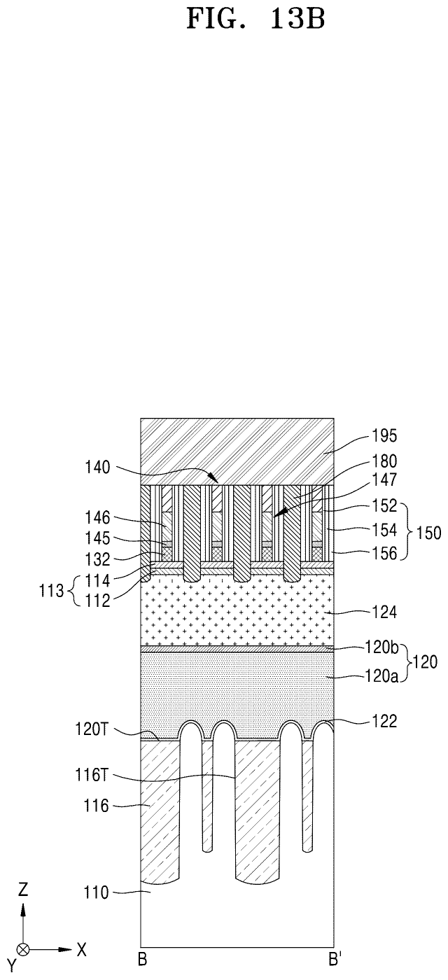

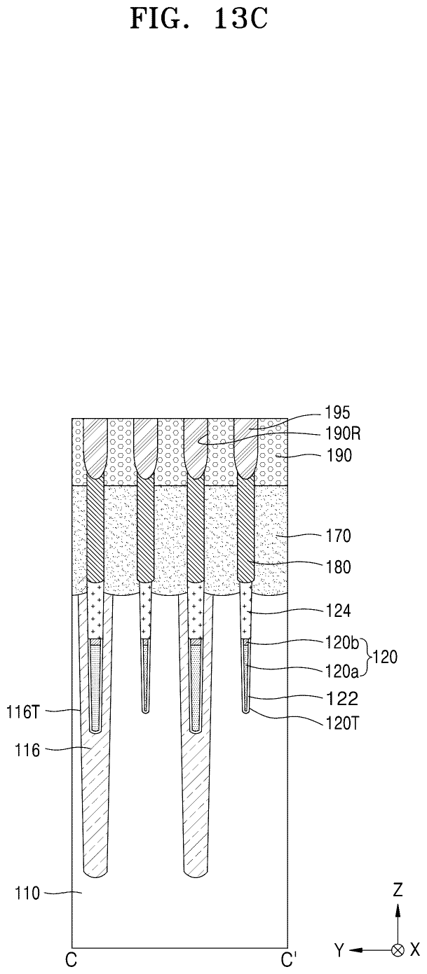

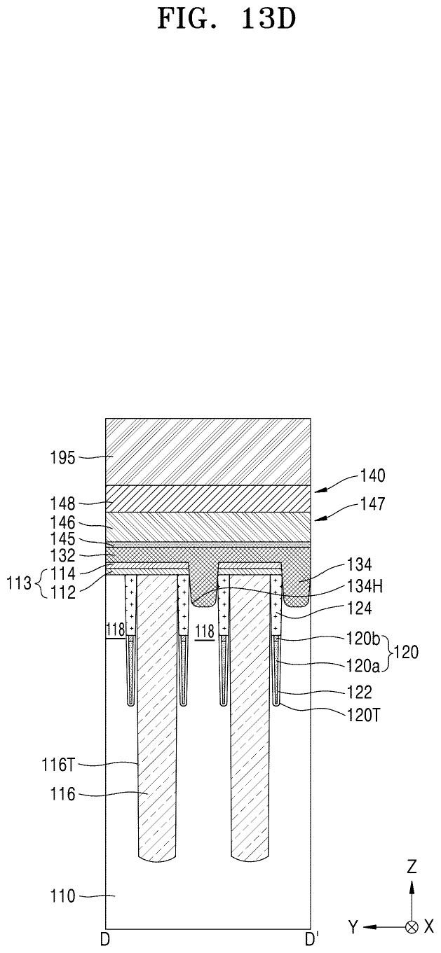

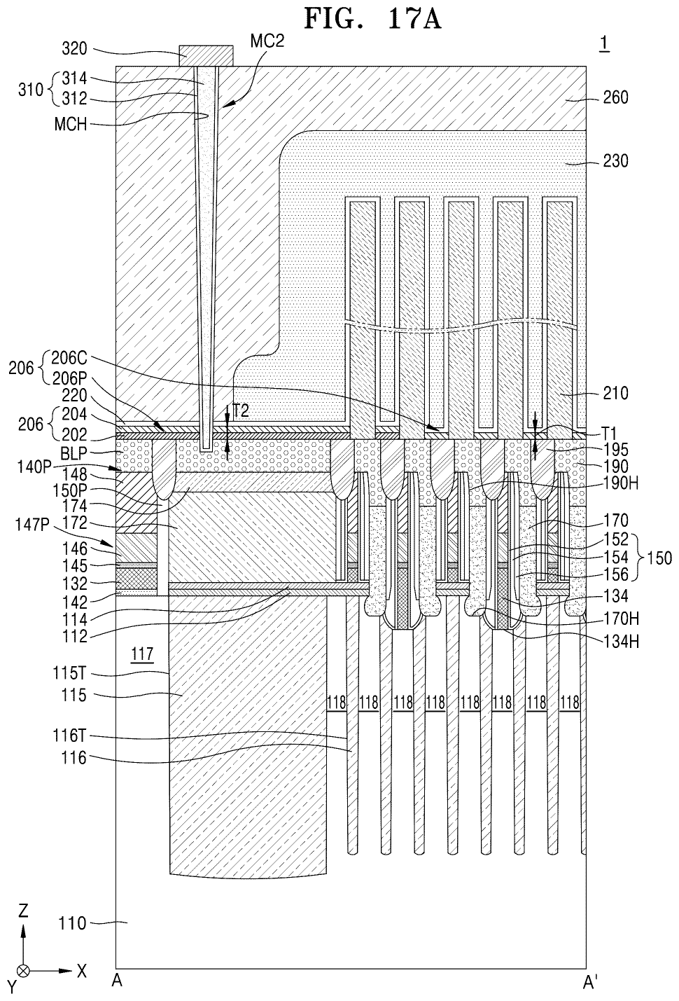

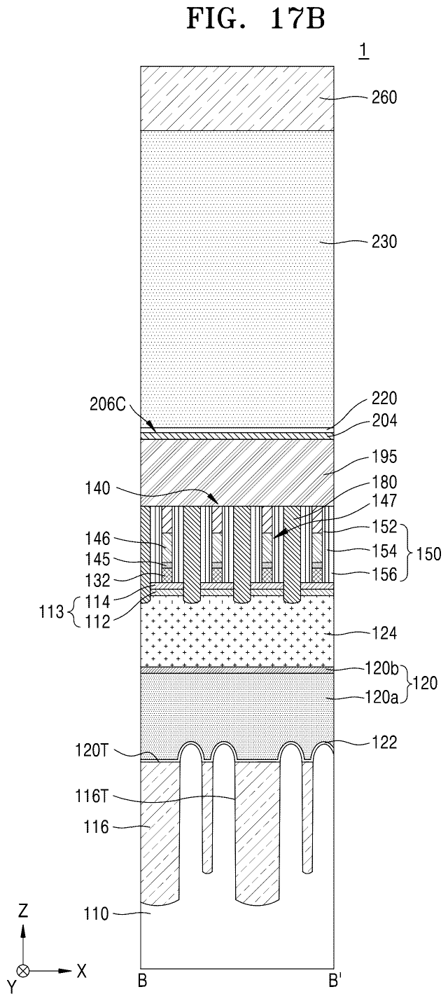

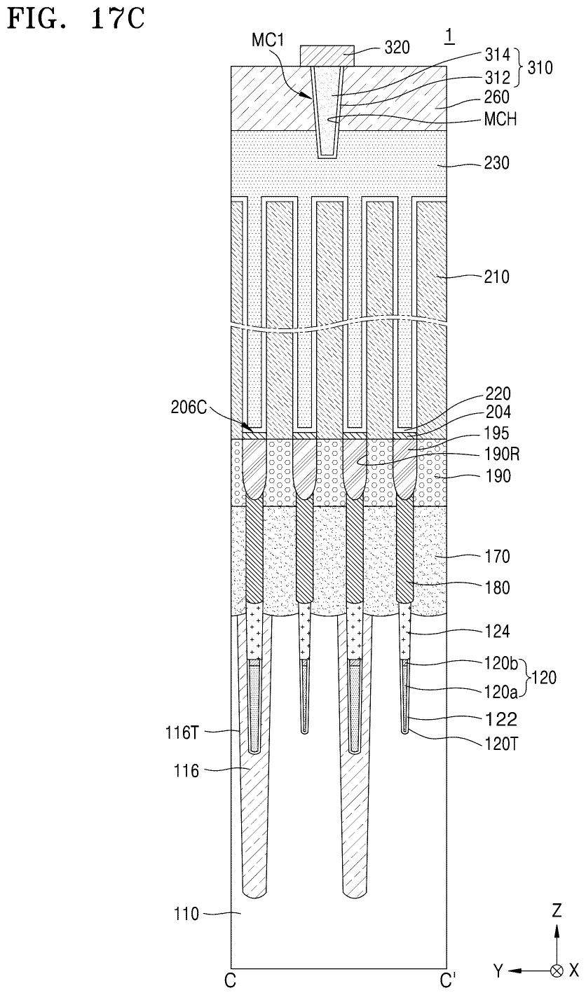

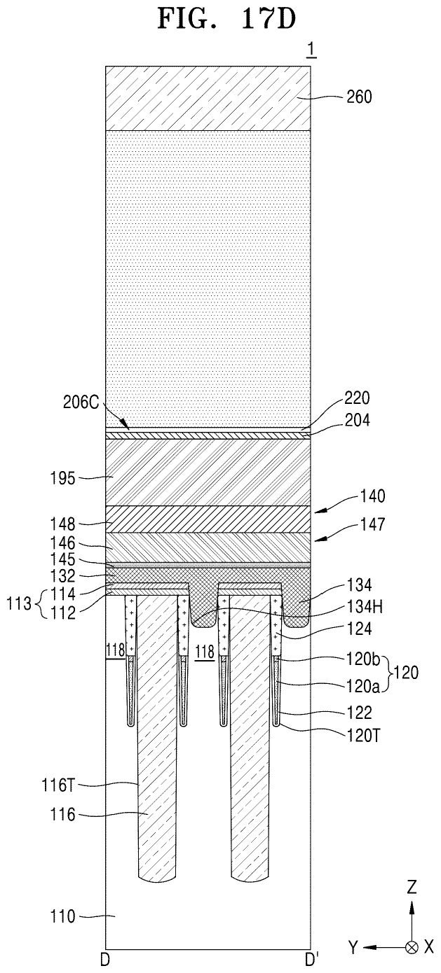

FIGS. 3A to 3D, 4A to 4D, 5A to 5D, 6A to 6D, 7A to 7D, 8A to 8D, 9A to 9D, 10A to 10D, 11A to 11D, 12A to 12D, 13A to 13D, 14A to 14D, 15A to 15D, and 16A to 16D are cross-sectional views illustrating a method of manufacturing a semiconductor memory device according to embodiments, and FIGS. 17A to 17D are cross-sectional views illustrating a semiconductor memory device according to embodiments. In detail, FIGS. 3A, 4A, 5A, 6A, 7A, 8A, 9A, 10A, 11A, 12A, 13A, 14A, 15A, 16A, and 17A are cross-sectional views taken along a position corresponding to line A-A′ of FIG. 2, FIGS. 3B, 4B, 5B, 6B, 7B, 8B, 9B, 10B, 11B, 12B, 13B, 14B, 15B, 16B, and 17B are cross-sectional views taken along a position corresponding to line B-B′ of FIG. 2, FIGS. 3C, 4C, 5C, 6C, 7C, 8C, 9C, 10C, 11C, 12C, 13C, 14C, 15C, 16C, and 17C are cross-sectional views taken along a position corresponding to line C-C′ of FIG. 2, and FIGS. 3D, 4D, 5D, 6D, 7D, 8D, 9D, 10D, 11D, 12D, 13D, 14D, 15D, 16D, and 17D are cross-sectional views taken along a position corresponding to line D-D′ of FIG. 2.

Referring to FIGS. 3A to 3D together, a trench 116T for device isolation and a trench 115T for logic device isolation may be formed in a substrate 110, and a device isolation film 116 filling the trench 116T for device isolation and a logic device isolation film 115 filling the trench 115T for logic device isolation may be formed. In some embodiments, the trench 116T for device isolation and a plurality of active regions 118 defined by the trench 116T for device isolation may be formed through an extreme ultraviolet (EUV) lithography process.

In some embodiments, the substrate 110 may include silicon (Si), crystalline Si, polycrystalline Si, or amorphous Si. In some embodiments, the substrate 110 may include a semiconductor element, such as germanium (Ge) or at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide layer (BOX) layer. The substrate 110 may include a conductive region, for example, a well doped with impurities or a structure doped with impurities.

The device isolation film 116 and the logic device isolation film 115 may be formed of a material including at least one of, for example, a silicon oxide film, a silicon nitride film, and a silicon oxynitride film. The device isolation film 116 may include a single layer formed of one type of insulating film, a double layer formed of two types of insulating films, or a multilayer formed of a combination of at least three types of insulating films. For example, the device isolation film 116 may include multiple layers, for example a double layer, formed of an oxide film and a nitride film. However, according to embodiments, the configuration of the device isolation film 116 is not limited to that described above. The active regions 118 may be defined on the substrate 110 in the memory cell region (CR of FIG. 2) by the device isolation film 116, and a plurality of logic active regions 117 may be defined on the substrate 110 in the peripheral region (PR of FIG. 2) by the logic device isolation film 115.

In some embodiments, the device isolation film 116 and the logic device isolation film 115 may be formed together and may be referred to together as a device isolation structure. The device isolation film 116 may be a portion of the device isolation structure defining the active regions 118, and the logic device isolation film 115 may be a portion of the device isolation structure defining the logic active regions 117. At a boundary between the memory cell region CR and the peripheral region PR, the device isolation film 116 may not be clearly distinguished from the logic device isolation film 115.

As shown in FIG. 2, in a planar view the active region 118 may have a shorter axis and a longer axis. For example, the active region may have a relatively long island shape extending in a longer axis direction. The active regions 118 may be arranged in rows in a diagonal direction with respect to the first horizontal direction (the X direction) and the second horizontal direction (the Y direction) and may be arranged in rows in the second horizontal direction (the Y direction). The logic active region 117 may have a rectangular shape in a planar view, like the logic active region ACTP illustrated in FIG. 2, but this is an example, and the logic active region 117 may have various planar shapes, without being limited thereto.

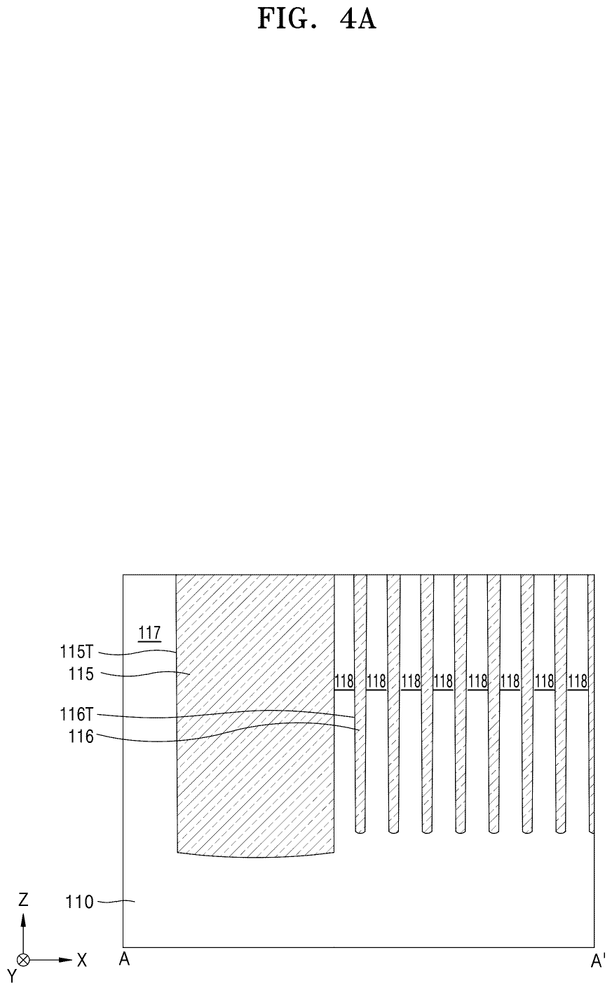

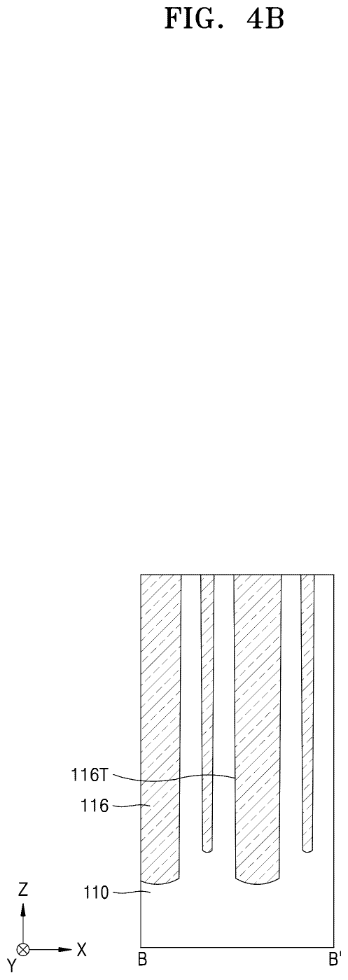

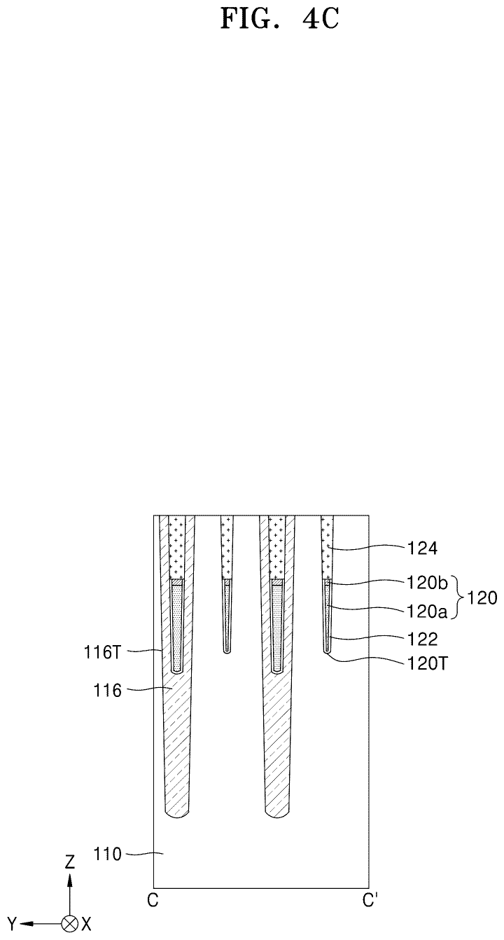

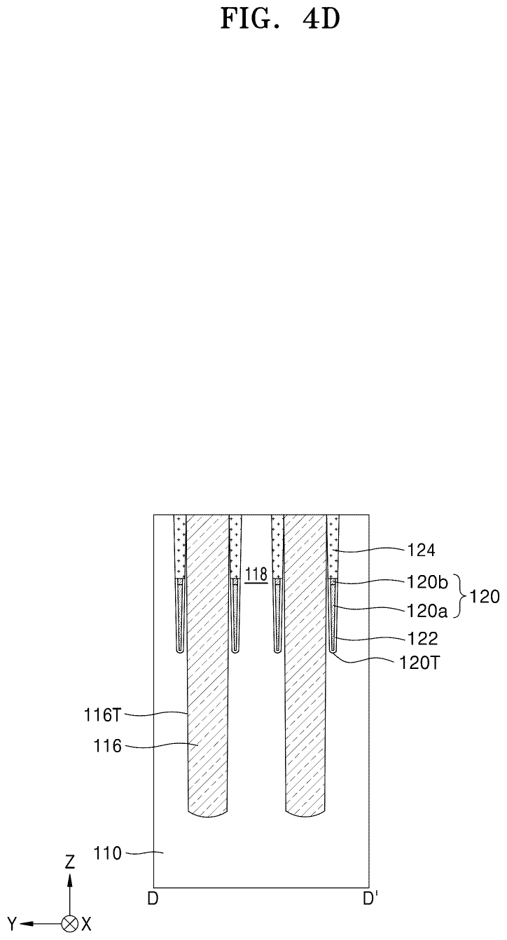

Referring to FIGS. 4A to 4D together, a portion of the active region 118 and a portion of the device isolation film 116 may be removed to form a plurality of word line trenches 120T in the substrate 110. The word line trenches 120T may have a line shape extending in the first horizontal direction (the X direction) parallel to each other and located at generally equal intervals in the second horizontal direction (the Y direction), while crossing the active region 118. In some embodiments, a step may be formed on a bottom surface of the word line trenches 120T.

A plurality of gate dielectric films 122, a plurality of word lines 120, and a plurality of buried insulating films 124 may be sequentially formed inside the word line trenches 120T. The word lines 120 may respectively constitute the word lines WL as illustrated in FIG. 2. The word lines 120 may have a line shape extending in parallel in the first horizontal direction (the X direction) and arranged at generally equal intervals in the second horizontal direction (the Y direction), while crossing the active region 118. An upper surface of each of the word lines 120 may be at a lower level than the upper surface of the substrate 110. The bottom surface of the word lines 120 may have a rough shape, and a saddle fin structure transistor (e.g., a saddle FinFET) may be formed in the active regions 118.

The terms “level” and “vertical level” refer to the height in the vertical direction (the Z direction) with respect to the main surface or upper surface of the substrate 110. That is, being at the same level or a constant level refers to a position at which the height in a vertical direction (a Z direction) with respect to the main surface or upper surface of the substrate 110 is the same or constant, and being at a low/high level means a position where the height in the vertical direction (the Z direction) with respect to the main surface of the substrate 110 is low/high.

Each of the word lines 120 may have a stack structure including a lower word line layer 120a and an upper word line layer 120b on the lower word line layer 120a. For example, the lower word line layer 120a may be formed of a metallic material, a conductive metal nitride, or combinations thereof. In some embodiments, the lower word line layer 120a include Ti, TiN, Ta, TaN, W, WN, TiSiN, WSiN, or combinations thereof. For example, the upper word line layer 120b may include doped polysilicon. In some embodiments, the lower word line layer 120a may include a core layer and a barrier layer located between the core layer and the gate dielectric film 122.

In some embodiments, before or after the word lines 120 are formed, impurity ions may be implanted into portions of the active regions 118 of the substrate 110 on both sides of the word lines 120 to form a source region and a drain region within the active regions 118.

The gate dielectric film 122 may include at least one selected from silicon oxide, silicon nitride, silicon oxynitride, oxide/nitride/oxide (ONO), or high-k dielectrics having a higher dielectric constant than silicon oxide. For example, the gate dielectric film 122 may have a dielectric constant of about 10 to 25.

The buried insulating film 124 may include at least one material selected from silicon oxide, silicon nitride, silicon oxynitride, or combinations thereof. In some embodiments, in the process of forming the gate dielectric films 122, the word lines 120, and the buried insulating films 124, an upper portion of the device isolation film 116 may be removed so that an upper surface of the substrate 110, an upper surface of the device isolation film 116, and upper surfaces of the buried insulating films 124 may be at substantially the same level to be coplanar.

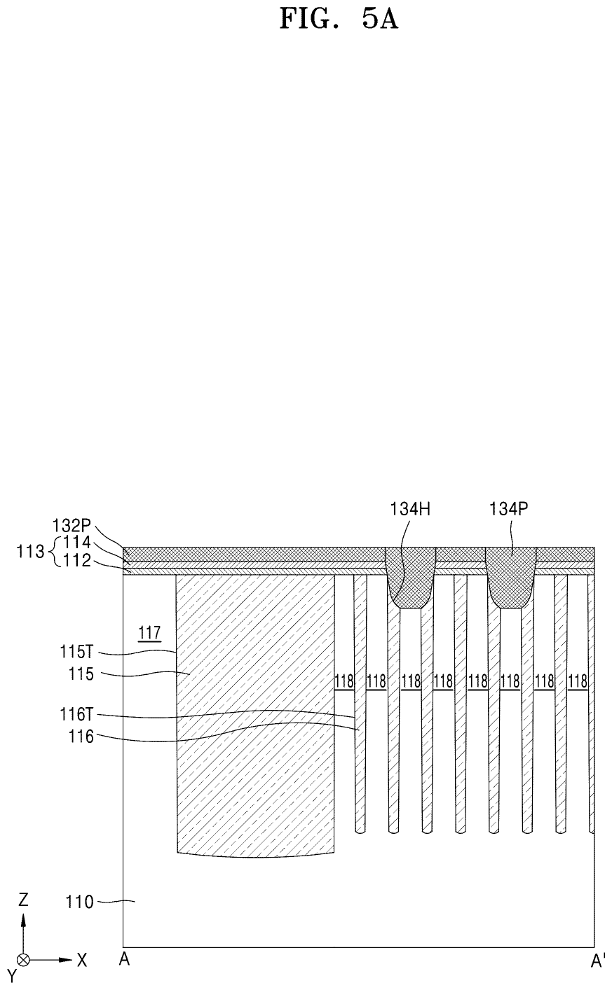

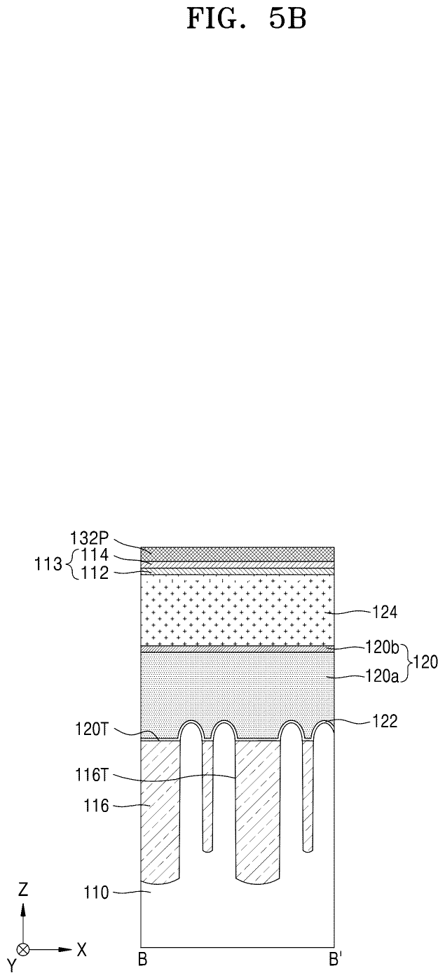

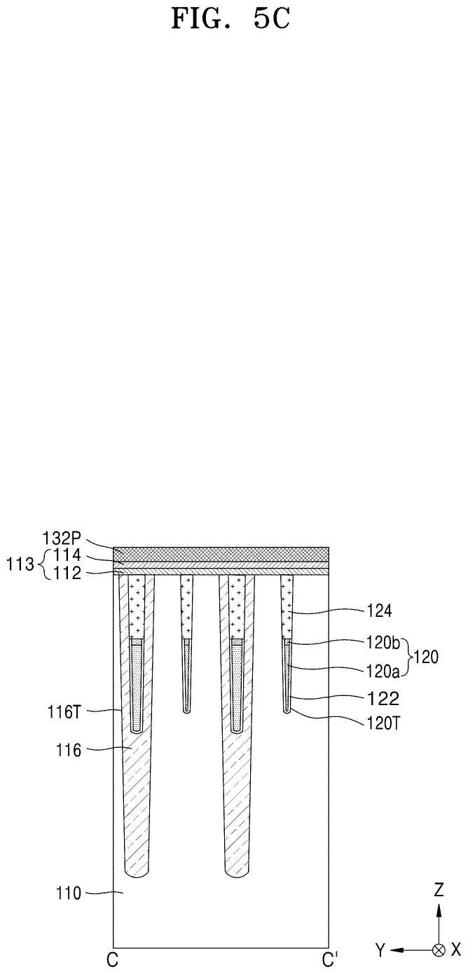

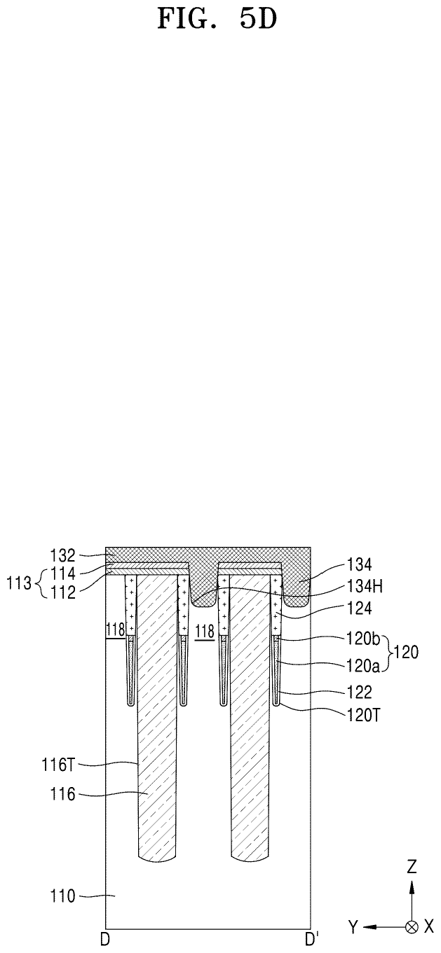

Referring to FIGS. 5A to 5D together, an insulating structure 113 covering the device isolation film 116, the active regions 118, the buried insulating films 124, the logic device isolation film 115, and the logic active regions 117 is formed. For example, the insulating structure 113 may include a silicon oxide film, a silicon nitride film, a silicon oxynitride film, a metal-based dielectric film, or combinations thereof. In some embodiments, the insulating structure 113 may be formed by stacking a plurality of insulating films including a first insulating film pattern 112 and a second insulating film pattern 114. In some embodiments, the first insulating film pattern 112 may include a silicon oxide film, and the second insulating film pattern 114 may include a silicon oxynitride film. In some other embodiments, the first insulating film pattern 112 may include a non-metallic dielectric film, such as a silicon oxide film, a silicon nitride film, or a silicon oxynitride film, and the second insulating film pattern 114 may include a metal dielectric film. In some embodiments, the second insulating film pattern 114 may be thicker than the first insulating film pattern 112. For example, the first insulating film pattern 112 may have a thickness of about 50 Å to about 90 Å, and the second insulating film pattern 114 may have a thickness of about 60 Å to about 100 Å. The second insulating film pattern 114 may be thicker than the first insulating film pattern 112.

A conductive semiconductor layer 132P is formed on the insulating structure 113, a direct contact hole 134H exposing a source region within the active region 118 through the conductive semiconductor layer 132P and the insulating structure 113 is formed, and then, a conductive layer 134P for direct contact is formed to fill the direct contact hole 134H. In some embodiments, the direct contact hole 134H may extend within the active region 118, i.e., within the source region. The conductive semiconductor layer 132P may include, for example, doped polysilicon. In some embodiments, the conductive semiconductor layer 132P and the conductive layer 134P for direct contact may include the same type of material. For example, the conductive layer 134P for direct contact may include doped polysilicon. In some other embodiments, the conductive semiconductor layer 132P and the conductive layer 134P for direct contact may include different types of materials. For example, the conductive layer 134P for direct contact may include an epitaxial silicon layer, a metal, or a metal compound that is a conductive material. In some embodiments, the conductive layer 134P for direct contact may include a metal, such as Ti and W, or a conductive material that is a compound of a metal, such as Ti and W, and a non-metal, such as Si, C, B, or N. For example, the conductive layer 134P for direct contact may include TiN, WC, or WSi.

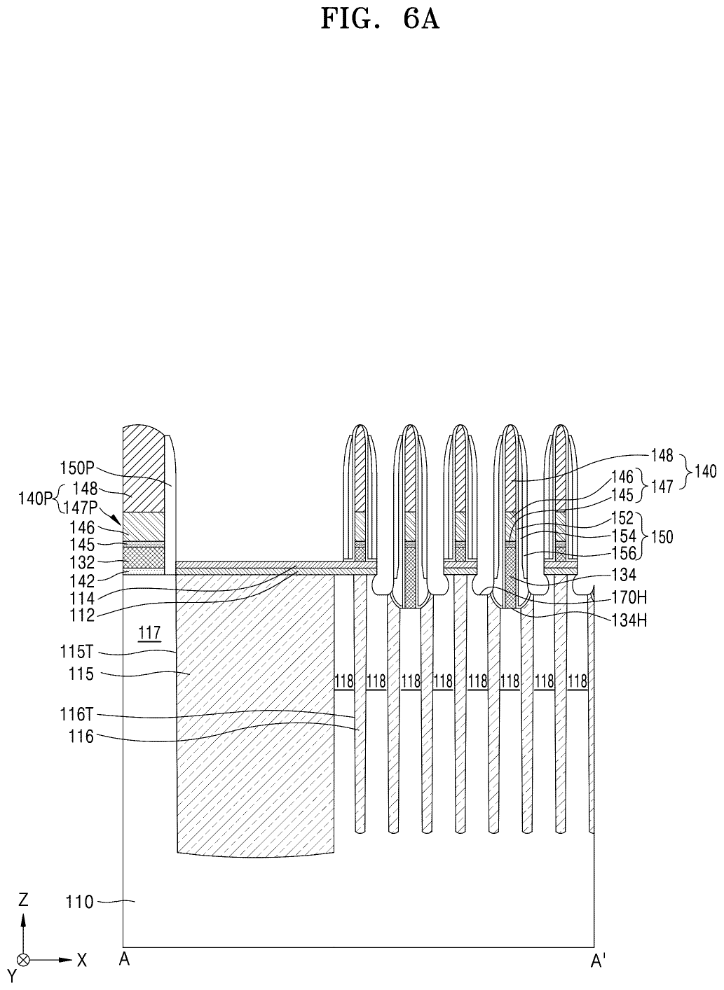

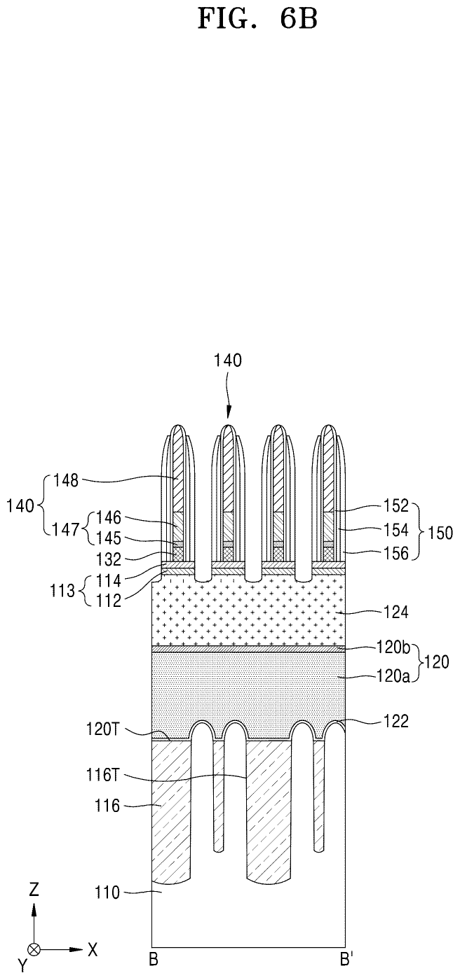

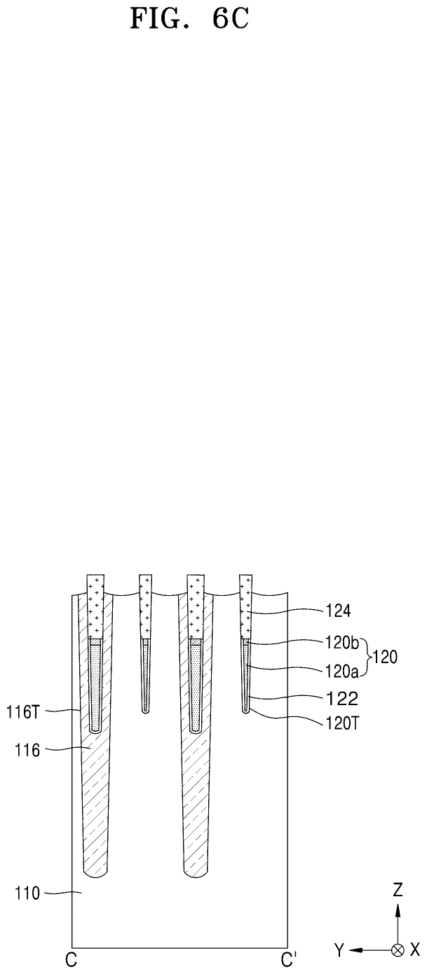

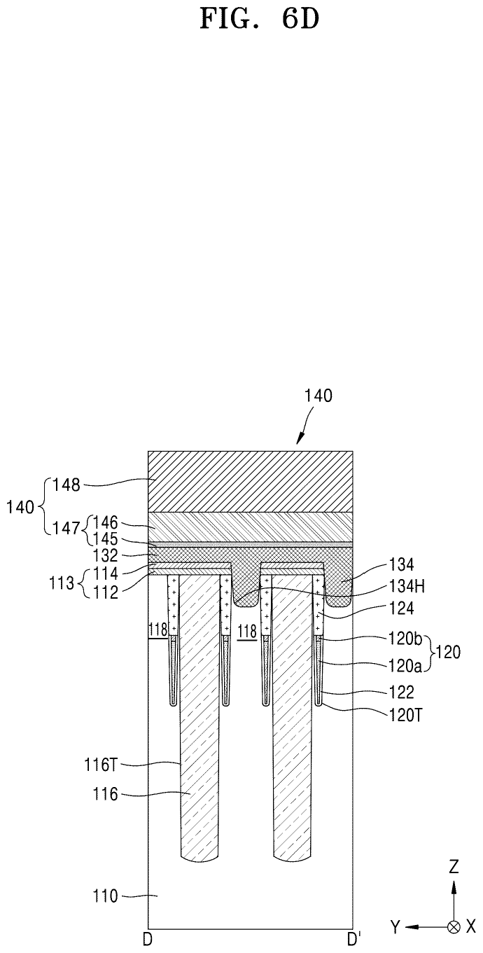

Referring to FIGS. 5A to 5D and FIGS. 6A to 6D together, a metal-based conductive layer for forming a bit line structure 140, while covering the conductive semiconductor layer 132P and the conductive layer 134P for direct contact, and an insulating capping layer are sequentially formed. In some embodiments, the metal-based conductive layer may have a stack structure including a first metal-based conductive layer and a second metal-based conductive layer on the first metal-based conductive layer. By etching the first metal-based conductive layer, the second metal-based conductive layer, and the insulating capping layer, a plurality of bit lines 147, each having a stack structure, and a plurality of insulating capping lines 148 respectively covering the bit lines 147 are formed. The stack structure may extend in a line shape, and may include a first metal-based conductive pattern 145 and a second metal-based conductive pattern 146 on the first metal-based conductive pattern 145.

In some embodiments, the first metal-based conductive pattern 145 may include titanium nitride (TiN) or Ti—Si—N (TSN), and the second metal-based conductive pattern 146 may include tungsten (W), or tungsten and tungsten silicide (WSix). In some embodiments, the first metal-based conductive pattern 145 may function as a diffusion barrier. In some embodiments, the insulating capping lines 148 may include a silicon nitride film.

One bit line 147 and one insulating capping line 148 covering one bit line 147 may constitute one bit line structure 140. The bit line structures 140, each including the bit line 147 and the insulating capping line 148 covering the bit line 147, may extend in the second horizontal direction (the Y direction) parallel to the main surface of the substrate 110 in a manner parallel to each other. The bit lines 147 may respectively form the bit lines BL as illustrated in FIG. 2. In some embodiments, the bit line structure 140 may further include a conductive semiconductor pattern 132 that is part of a conductive semiconductor layer 132P located between the insulating structure 113 and the first metal-based conductive pattern 145.

In an etching process for forming the bit lines 147, a portion of the conductive semiconductor layer 132P that does not vertically overlap the bit line 147 or a portion of the conductive layer 134P for direct contact may be removed together through an etching process to form the conductive semiconductor patterns 132 and a plurality of direct contact conductive patterns 134. Here, the insulating structure 113 may function as an etching stop film in an etching process of forming the bit lines 147, the conductive semiconductor patterns 132, and the direct contact conductive patterns 134. The direct contact conductive patterns 134 may constitute the direct contacts DC as illustrated in FIG. 2. The bit lines 147 may be electrically connected to the active regions 118 through the direct contact conductive patterns 134. The conductive semiconductor pattern 132 may include, for example, doped polysilicon. The direct contact conductive pattern 134 may include doped polysilicon, a metal, or a metal compound that is a conductive material. For example, the direct contact conductive pattern 134 may include a metal, such as Ti and W, or a conductive material that is a compound of a metal, such as Ti and W, and a non-metal, such as Si, C, B, or N. In some embodiments, the direct contact conductive pattern 134 may include TiN, WC, or WSi.

Both sidewalls of each of the bit line structures 140 may be covered with an insulating spacer structure 150. Each of the insulating spacer structures 150 may include a first insulating spacer 152, a second insulating spacer 154, and a third insulating spacer 156. The second insulating spacer 154 may include a material having a lower permittivity than the first insulating spacer 152 and the third insulating spacer 156. In some embodiments, the first insulating spacer 152 and the third insulating spacer 156 may include a nitride film, and the second insulating spacer 154 may include an oxide film. In some embodiments, the first insulating spacer 152 and the third insulating spacer 156 may include a nitride film, and the second insulating spacer 154 may include a material having an etching selectivity with respect to the first insulating spacer 152 and the third insulating spacer 156. For example, when the first insulating spacer 152 and the third insulating spacer 156 include a nitride film, the second insulating spacer 154 may include an oxide film but may be removed in a subsequent process to become an air spacer.

A plurality of buried contact holes 170H may be formed between each of the bit lines 147. An internal space of the buried contact holes 170H may be limited by the insulating spacer structure 150 covering the sidewalls of each of two adjacent bit lines 147 among the bit lines 147 and the active region 118.

The buried contact holes 170H may be formed by removing a portion of the insulating structure 113 and the active region 118 using the insulating spacer structure 150 covering both sidewalls of each of the insulating capping lines 148 and the bit line structures 140 as an etching mask. In some embodiments, the buried contact holes 170H may be formed by first performing an anisotropic etching process to remove a portion of the insulating structure 113 and the active region 118 using an insulating spacer structure 150 covering both sidewalls of each of the insulating capping lines 148 and the bit line structures 140 as an etching mask, and then performing an isotropic etching process to further remove another portion of the active region 118, so that the space defined by the active region 118 is expanded.

A plurality of gate line structures 140P may be formed on the logic active region 117. The gate line structure 140P may include a gate line 147P and an insulating capping line 148 covering the gate line 147P. A plurality of gate lines 147P included in the gate line structures 140P may be formed together with the bit lines 147. For example, the gate lines 147P may be formed at the same level as the bit lines 147. In some embodiments, the gate lines 147P and the bit lines 147 may include the same material or at least partially include the same material. For example, the process of forming all or part of the gate lines 147P and the process of forming all or part of the bit lines 147 may be the same process.

The gate line 147P may have a stack structure including the first metal-based conductive pattern 145 and the second metal-based conductive pattern 146 on the first metal-based conductive pattern 145. A gate insulating film pattern 142 may be located between the gate line 147P and the logic active region 117. In some embodiments, the gate line structure 140P may further include a conductive semiconductor pattern 132 located between the gate insulating film pattern 142 and the first metal-based conductive pattern 145. The gate lines 147P may form the gate lines GLP as illustrated in FIG. 2.

The sidewall of the gate line structure 140P may be covered by a gate insulating spacer 150P. The gate insulating spacer 150P may include, for example, a nitride film. In some embodiments, the gate insulating spacer 150P may include a single layer but embodiments are not limited thereto, For example, the gate insulating spacer 150P may include a plurality of stack structures having two or more layers. For example, the gate insulating spacer 150P may be formed to have a stack structure including at least three layers, similar to the insulating spacer structure 150.

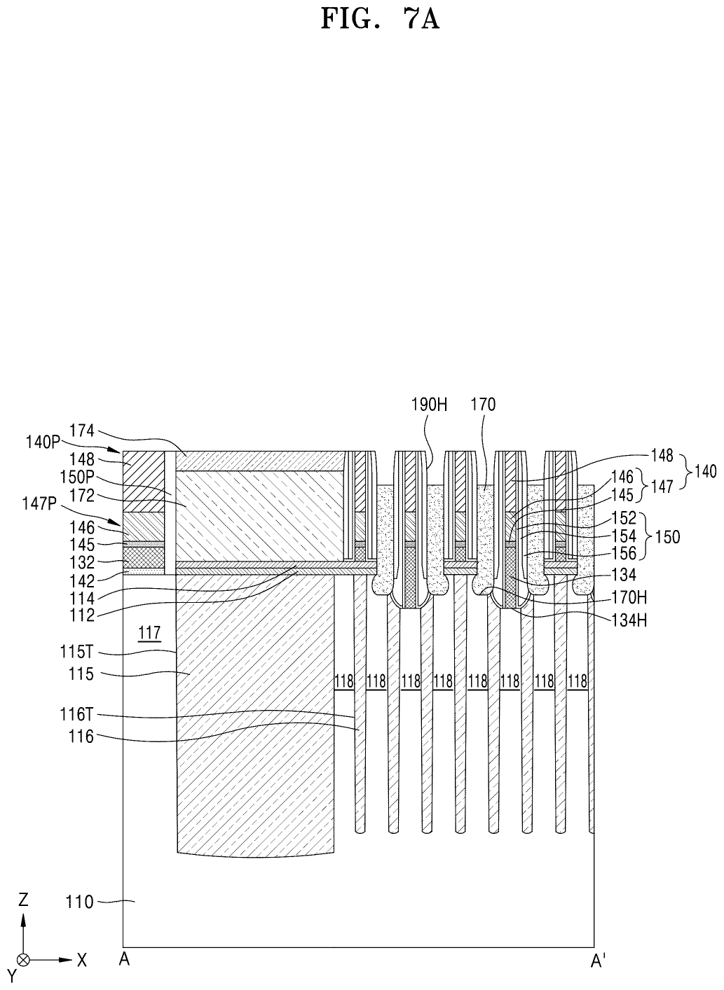

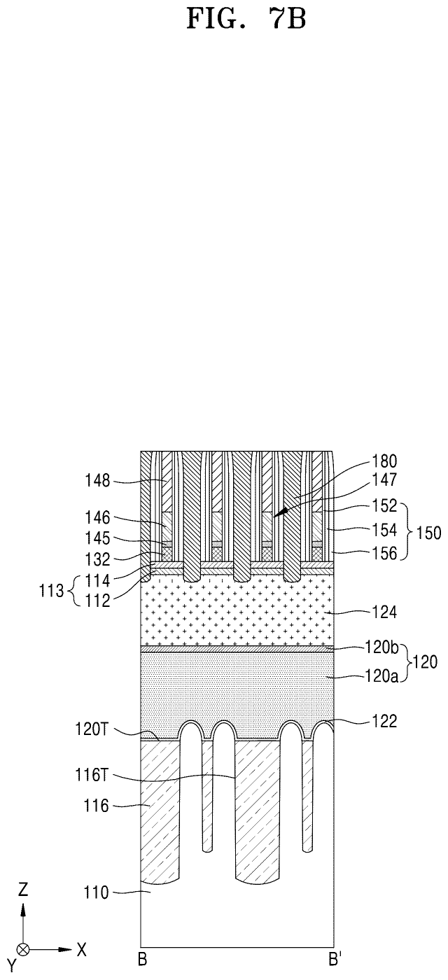

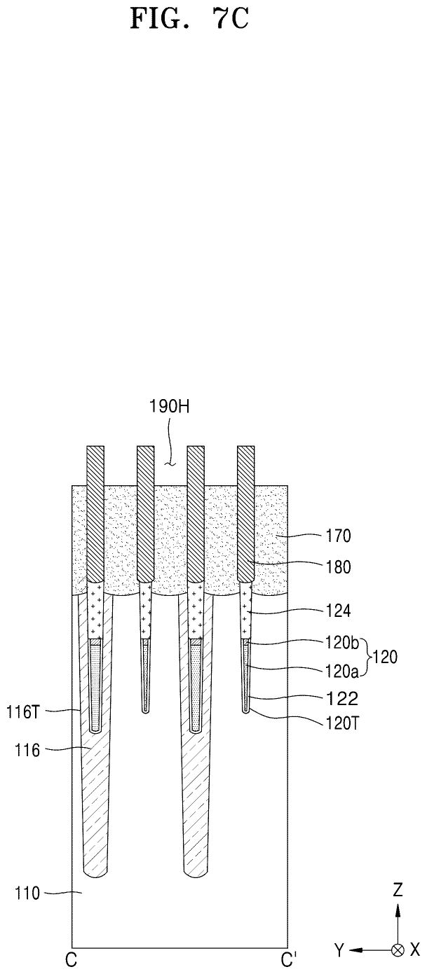

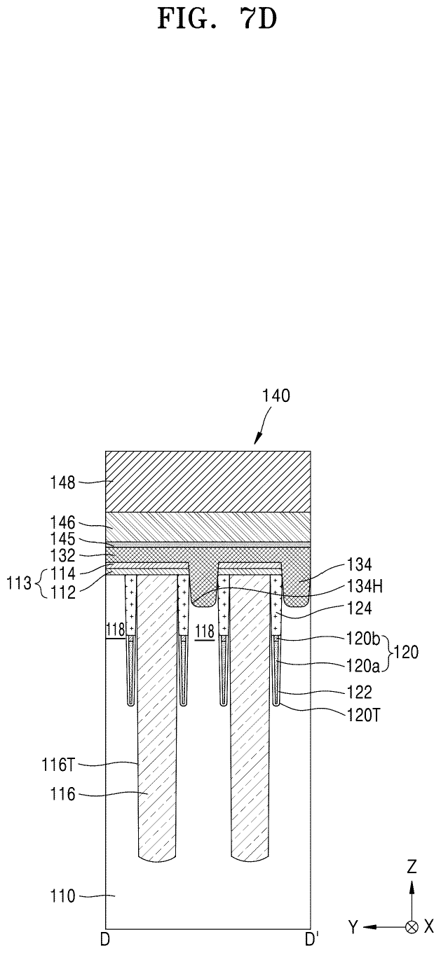

Referring to FIGS. 7A to 7D together, a plurality of buried contacts 170 and a plurality of insulating fences 180 are formed in a space between the insulating spacer structures 150 covering both sidewalls of each of the bit line structures 140. The buried contacts 170 and the insulating fences 180 may be alternately arranged between a pair of insulating spacer structures 150 facing each other among the insulating spacer structures 150 covering both sidewalls of the bit line structures 140, i.e., in the second horizontal direction (the Y direction). For example, the buried contacts 170 may include polysilicon. For example, the insulating fences 180 may include a nitride film.

In some embodiments, the buried contacts 170 may be arranged in rows extending in each of the first horizontal direction (the X direction) and the second horizontal direction (the Y direction). Each of the buried contacts 170 may extend in the vertical direction (the Z direction) perpendicular to the substrate 110 from the active region 118. The buried contacts 170 may respectively configure the buried contacts BC illustrated in FIG. 2.

The buried contacts 170 may be arranged in a space defined by the insulating fences 180 and the insulating spacer structures 150 covering both sidewalls of the bit line structures 140. The buried contacts 170 may fill a lower portion of the space between the insulating spacer structures 150 covering both sidewalls of each of the bit line structures 140.

The level of upper surfaces of the buried contacts 170 may be lower than the level of upper surfaces of the insulating capping lines 148. Upper surfaces of the insulating fences 180 and the upper surfaces of the insulating capping lines 148 may be at the same level with respect to the vertical direction (the Z direction).

A plurality of landing pad holes 190H may be defined by the insulating spacer structures 150 and the insulating fences 180. The buried contacts 170 may be exposed at the bottom surface of the landing pad holes 190H.

A stack structure including a first interlayer insulating layer 172 and a second interlayer insulating layer 174 on the first interlayer insulating layer 172 may be formed on an insulating structure 113 near the gate line structures 140P. In some embodiments, the first interlayer insulating layer 172 may include an oxide, and the second interlayer insulating layer 174 may include a nitride. An upper surface of the second interlayer insulating layer 174 and an upper surface of the gate line structure 140P may have the same level. The stack structure including the first interlayer insulating layer 172 and the second interlayer insulating layer 174 may be referred to as an interlayer insulating layer.

In the process of forming the buried contacts 170 and/or the insulating fences 180, an upper portion of the bit line structure 140 and upper portions of the insulating capping line 148, the insulating spacer structure 150, and the gate insulating spacer 150P included in the gate line structure 140P may be removed so that the level of the upper surface of the bit line structure 140 and the level of the upper surface of the gate line structure 140P may be lowered.

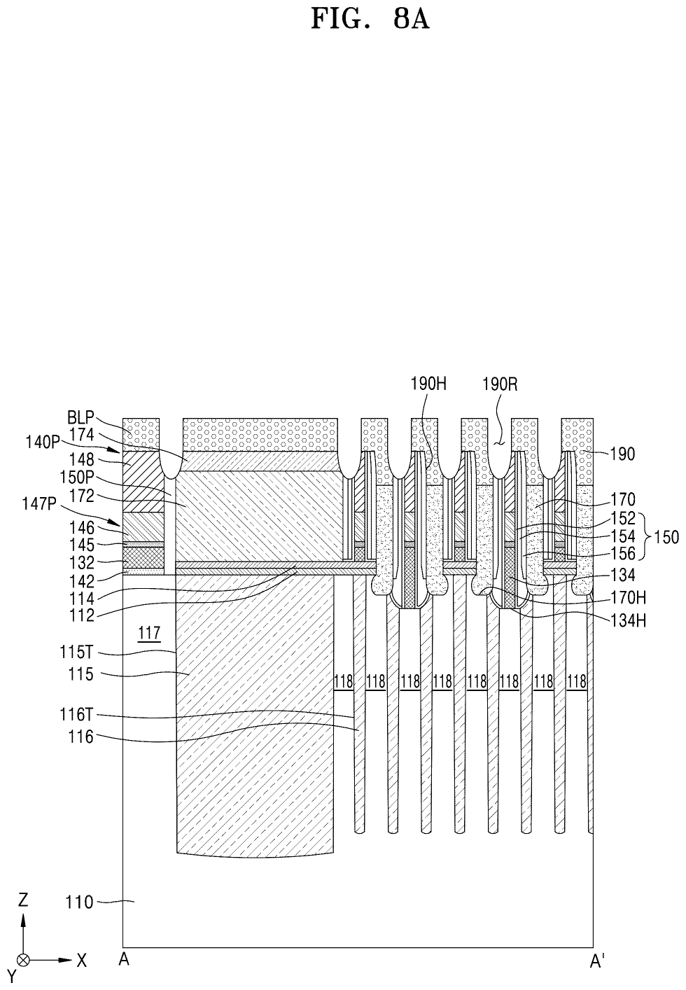

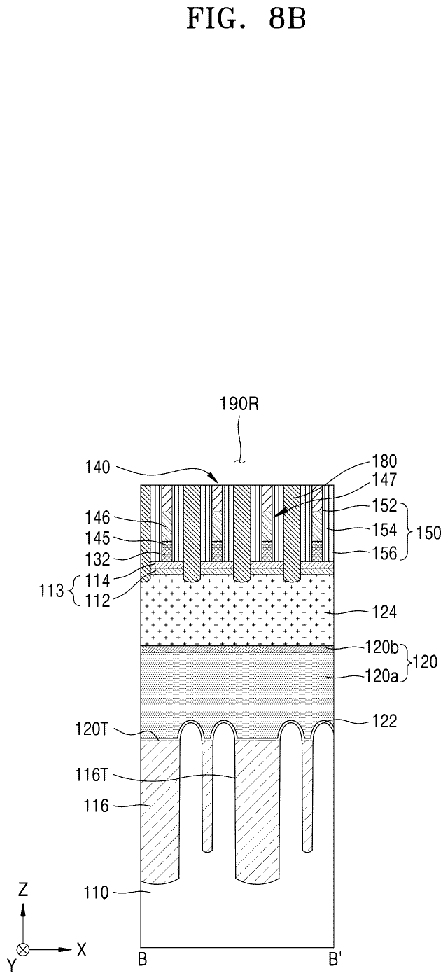

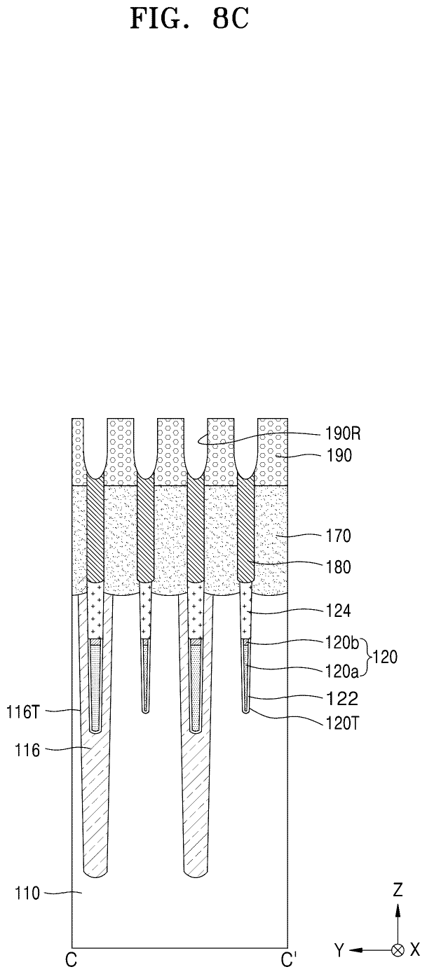

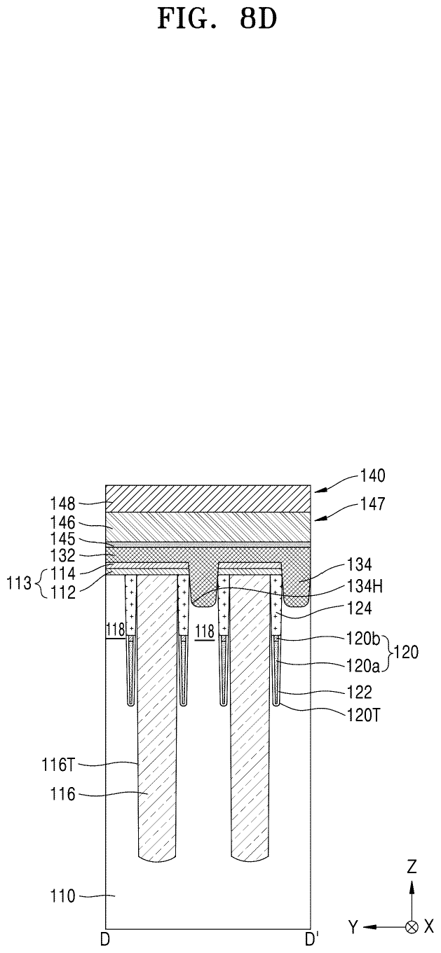

Referring to FIGS. 8A to 8D together, a landing pad material layer filling the landing pad holes 190H and covering the bit line structures 140, the gate line structures 140P, and the second interlayer insulating layer 174 is formed. In some embodiments, the landing pad material layer may include a conductive barrier film and a conductive pad material layer on the conductive barrier film. For example, the conductive barrier film may include a metal, a conductive metal nitride, or combinations thereof. In some embodiments, the conductive barrier film may include a Ti/TiN stack structure. In some embodiments, the conductive pad material layer may include tungsten (W).

In some embodiments, a metal silicide film may be formed on the buried contacts 170 prior to forming the landing pad material layer. The metal silicide film may be located between the buried contacts 170 and the landing pad material layer. The metal silicide film may include, but is not limited to, cobalt silicide (CoSix), nickel silicide (NiSix), or manganese silicide (MnSix).

A portion of the landing pad material layer is removed to form a plurality of landing pads 190 that fill at least a portion of the landing pad holes 190H, extend onto the bit line structures 140, and are separated into the plurality of landing pads 190 by recessed portions 190R.

The landing pads 190 may be apart from each other with the recessed portion 190R therebetween. The landing pads 190 may be respectively arranged on the buried contacts 170 and may extend onto the bit line structures 140. In some embodiments, the landing pads 190 may extend over the bit lines 147. The landing pads 190 may be arranged on the buried contacts 170 so that the buried contacts 170 may be electrically connected to the landing pads 190 respectively corresponding thereto. The buried contact 170 and the landing pad 190 that correspond to each other may be collectively referred to as a contact plug. The landing pads 190 may be connected to the active region 118 via the buried contacts 170. The landing pads 190 may respectively configure the landing pads LP illustrated in FIG. 2.

The buried contact 170 may be located between two adjacent bit line structures 140, and the landing pad 190 may extend from between two adjacent bit line structures 140 with the buried contact 170 therebetween onto one bit line structure 140.

A plurality of logic bit lines BLP may be arranged on the gate line structure 140P. For example, the logic bit lines BLP may extend along the insulating capping line 148 of the gate line structure 140P and/or the stack structure including the first interlayer insulating layer 172 and the second interlayer insulating layer 174. Each of the logic bit lines BLP may be part of the landing pad material layer. At least a portion of each of the landing pads 190 may be at the same vertical level as that of the logic bit lines BLP.

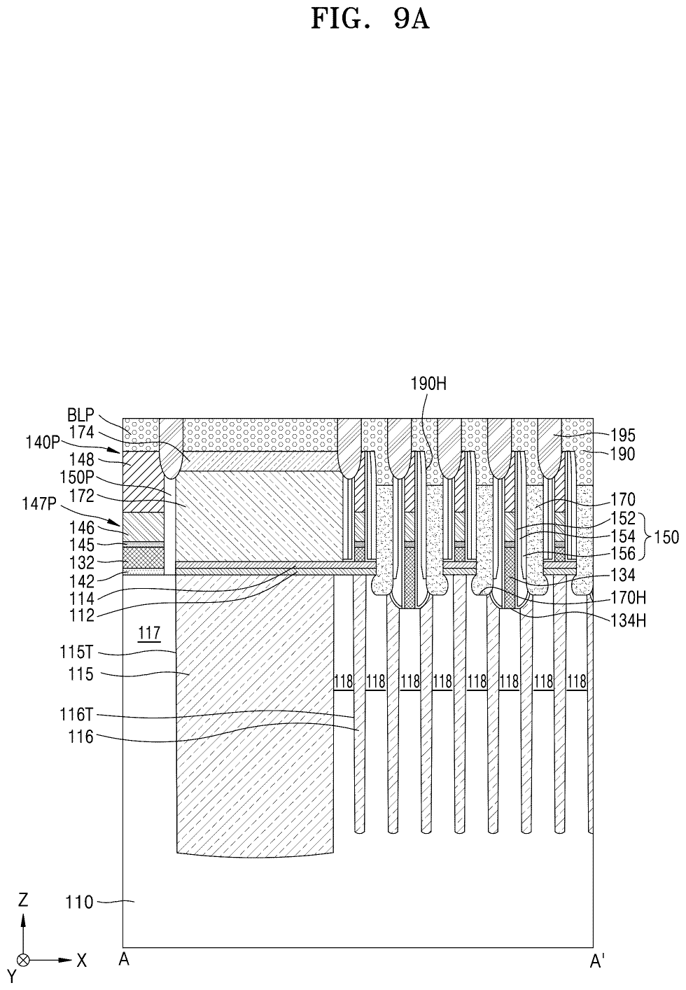

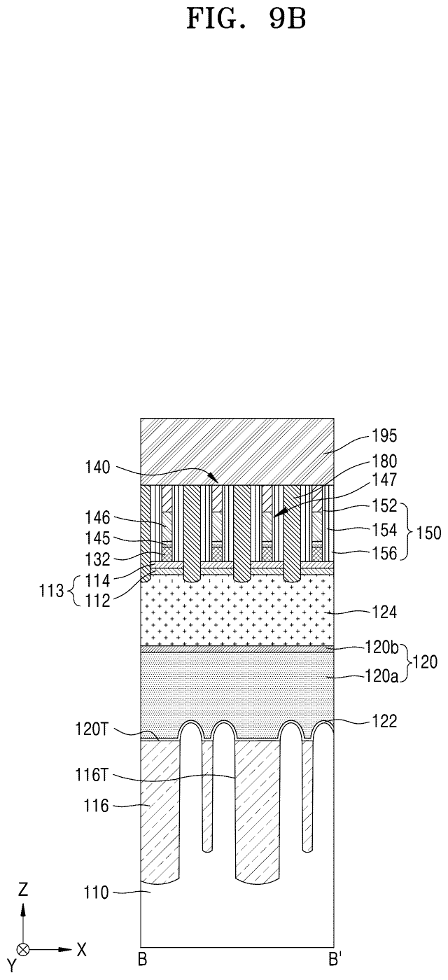

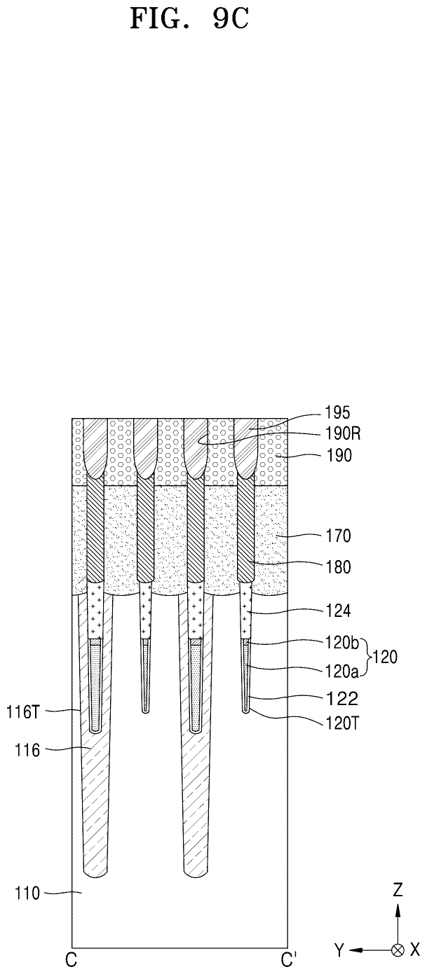

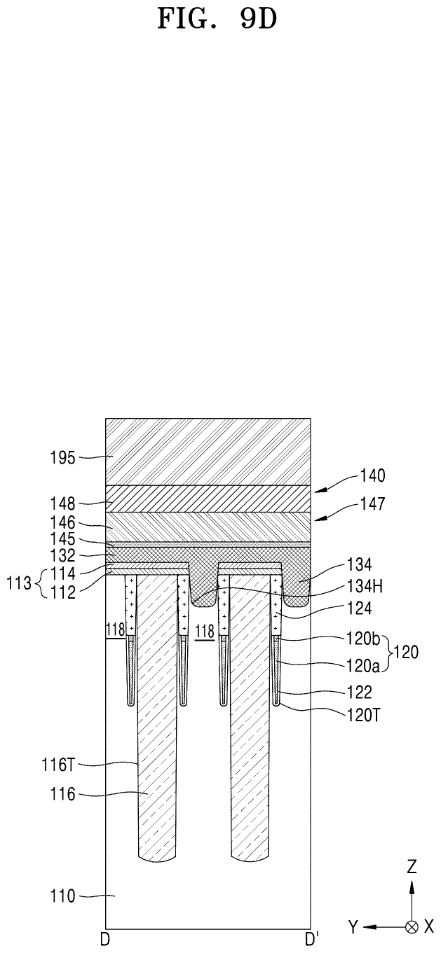

Referring to FIGS. 9A to 9D together, a filling insulating layer 195 filling the recessed portion 190R may be formed. The filling insulating layer 195 may include nitride. For example, the filling insulating layer 195 may include silicon nitride. In some embodiments, the filling insulating layer 195 may have a stack structure including an oxide film and a nitride film. For example, the nitride film may be on the oxide film. For example, the oxide film may be on the nitride film. The landing pads 190 may be separated from each other by the filling insulating layer 195 filling the recessed portion 190R. In FIGS. 9A and 9C, the upper surface of the filling insulating layer 195 is illustrated as being at the same level as that of the upper surface of the landing pad 190 but embodiments are not limited thereto. In some embodiments, the filling insulating layer 195 may fill the space between the logic bit lines BLP.

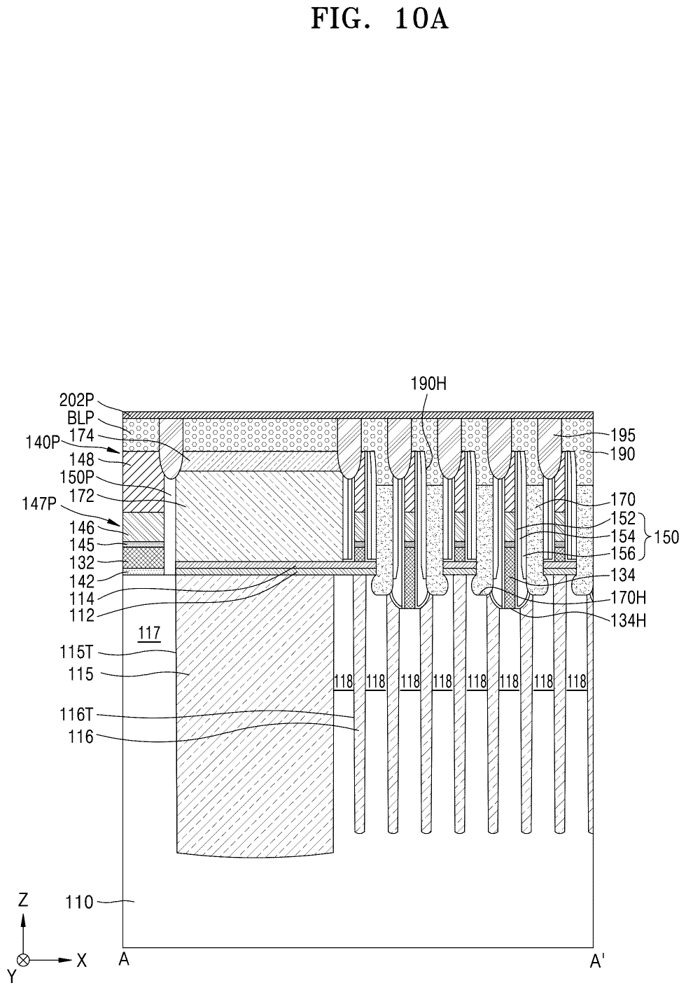

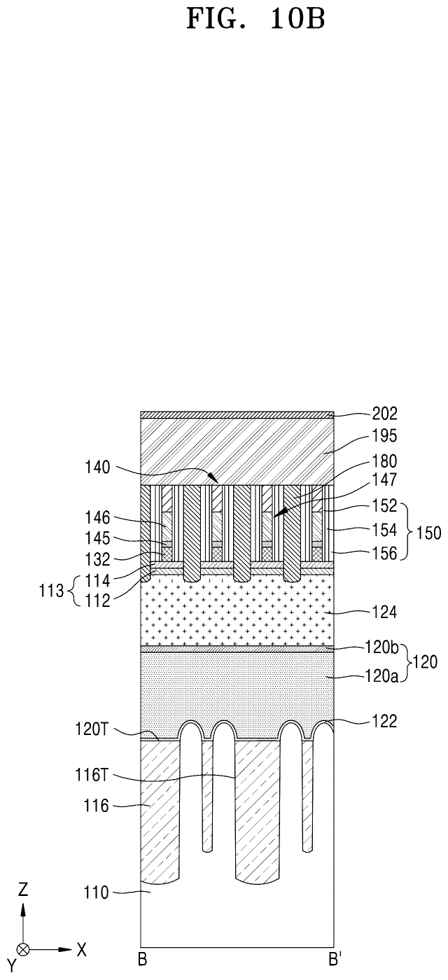

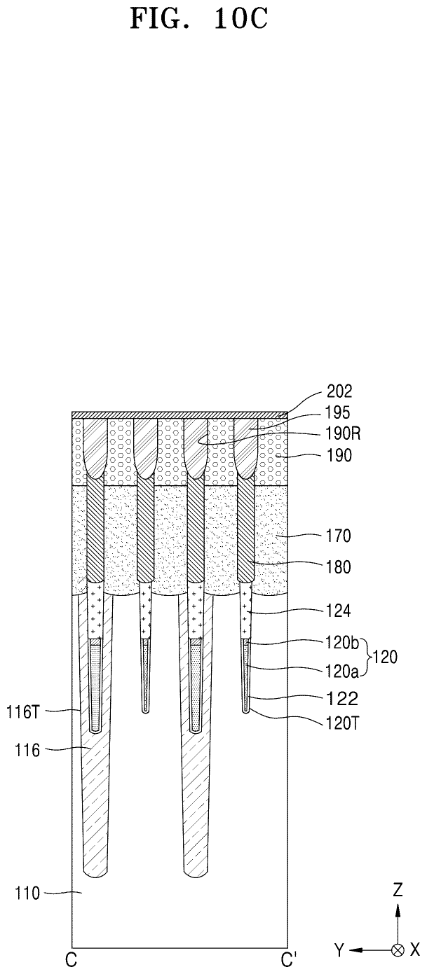

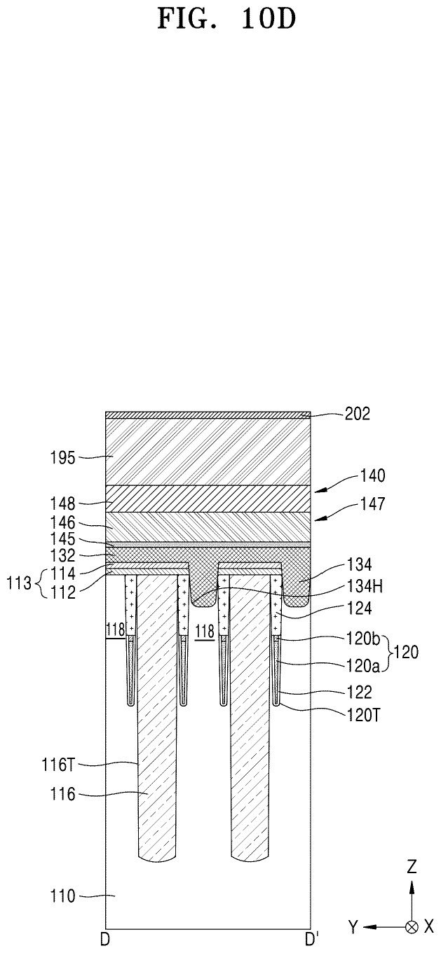

Referring to FIGS. 10A to 10D together, a lower etch stop material layer 202P covering the landing pads 190, the logic bit lines BLP, and the filling insulating layer 195 is formed. The lower etch stop material layer 202P may include a material having etching characteristics that are different from silicon oxide and silicon nitride. For example, the lower etch stop material layer 202P may include SiBN, SiCN, SiC, SiON, SiCO, SiCON, SiBC, SiBON, SiBCO, SiBCN, or SiBCON.

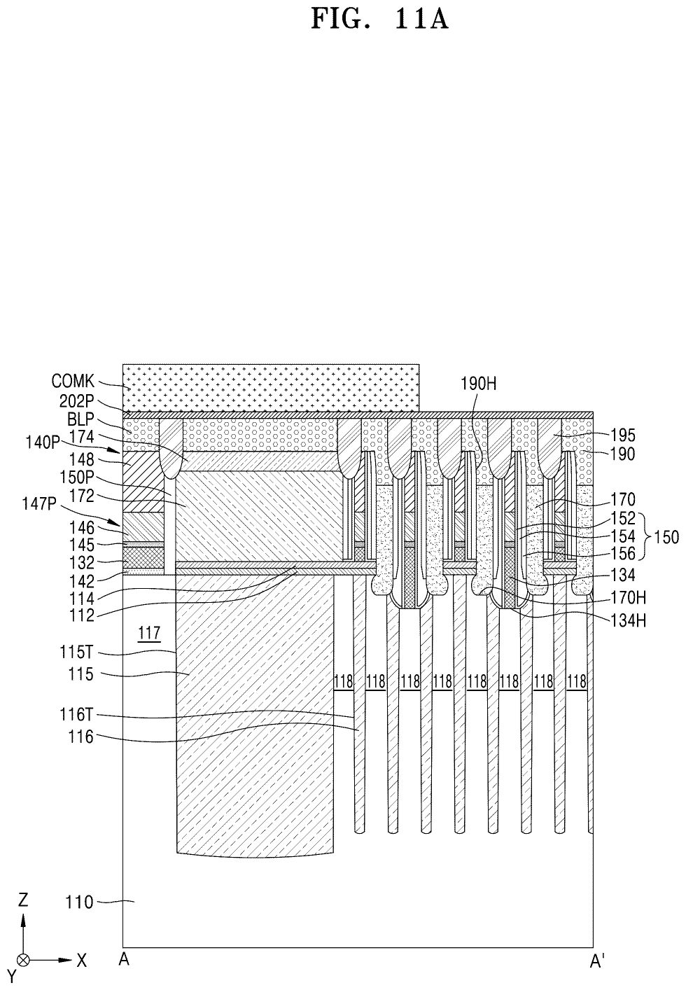

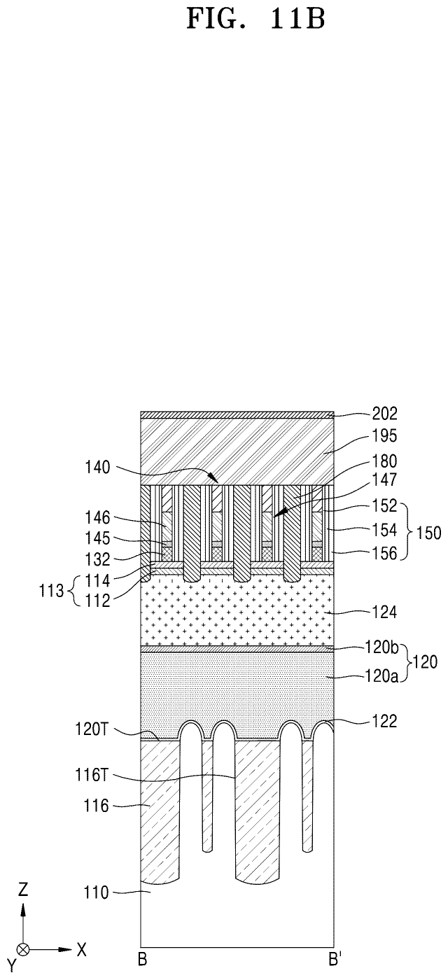

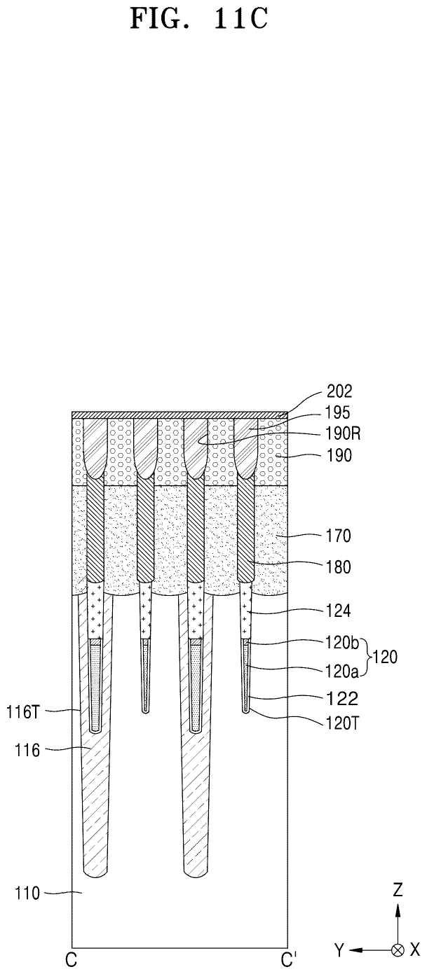

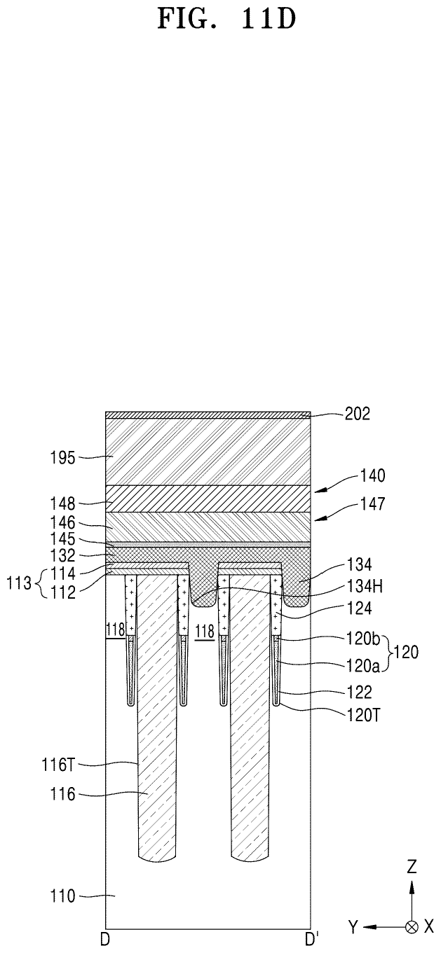

Referring to FIGS. 11A to 11D together, a cell open mask pattern COMK is formed on the lower etch stop material layer 202P. The cell open mask pattern COMK may be formed to cover the peripheral region (PR in FIG. 2) but not cover a portion of the memory cell region (CR in FIG. 2). The cell open mask pattern COMK may be formed to cover a portion of the memory cell region CR adjacent to the peripheral region PR and the peripheral region PR. For example, the cell open mask pattern COMK may be formed to cover an edge region of the memory cell region CR but not cover an inner region surrounded by the edge region of the memory cell region CR.

The cell open mask pattern COMK may be formed to overlap some of the landing pads 190 adjacent to the peripheral region PR in the vertical direction (the Z direction) but not to overlap the other landing pads 190. For example, the cell open mask pattern COMK may be formed to overlap the landing pads 190 adjacent to each of four edges of the memory cell region CR, which is the boundary between the peripheral region PR and the memory cell region CR, among the landing pads 190 and arranged to form at least one row along each of the four edges of the memory cell region CR.

Referring to FIGS. 11A to 11D, 12A to 12D, and 13A to 13D together, a portion of the lower etch stop material layer 202P that is not covered by the cell open mask pattern COMK is removed to form a lower etch stop layer 202. The lower etch stop layer 202 may be formed to cover the edge region of the memory cell region CR but not to cover an inner region surrounded by the edge region of the memory cell region CR. After the lower etch stop layer 202 is formed, the cell open mask pattern COMK is removed.

The lower etch stop layer 202 may be formed to cover some of the landing pads 190 adjacent to the peripheral region PR but not to cover the other landing pads 190. For example, the lower etch stop layer 202 may be formed to cover the landing pads 190 adjacent to each of four edges of the memory cell region CR, which is the boundary between the peripheral region PR and the memory cell region CR in the landing pads 190 and arranged to form at least one row along each of the four edges.

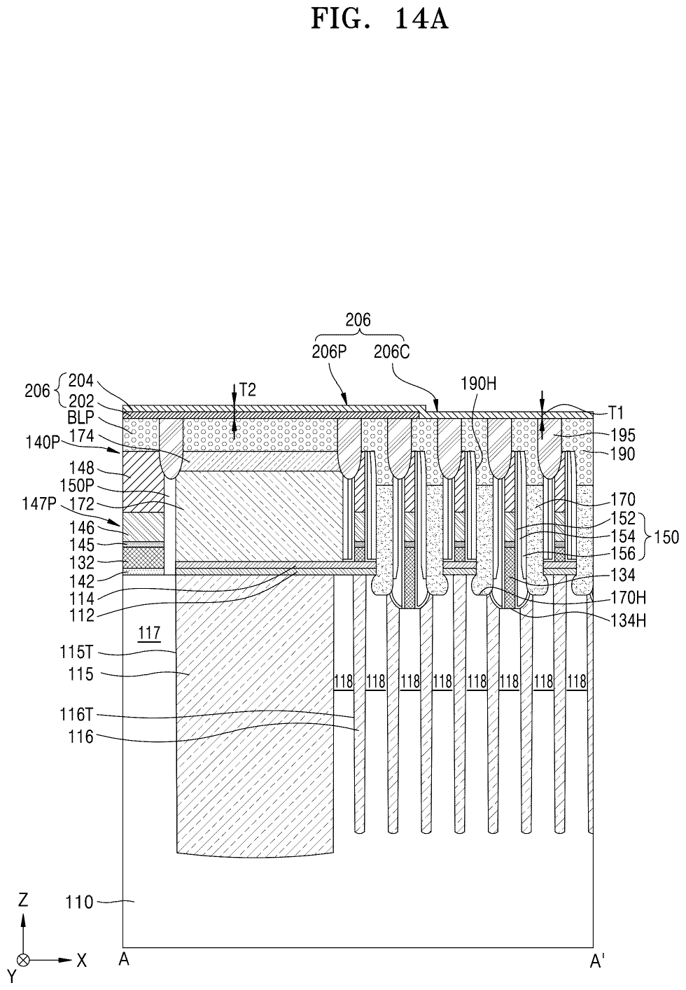

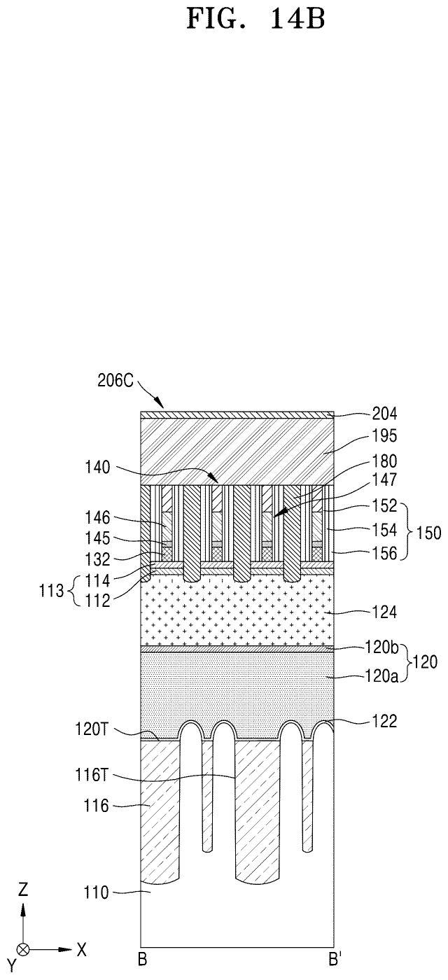

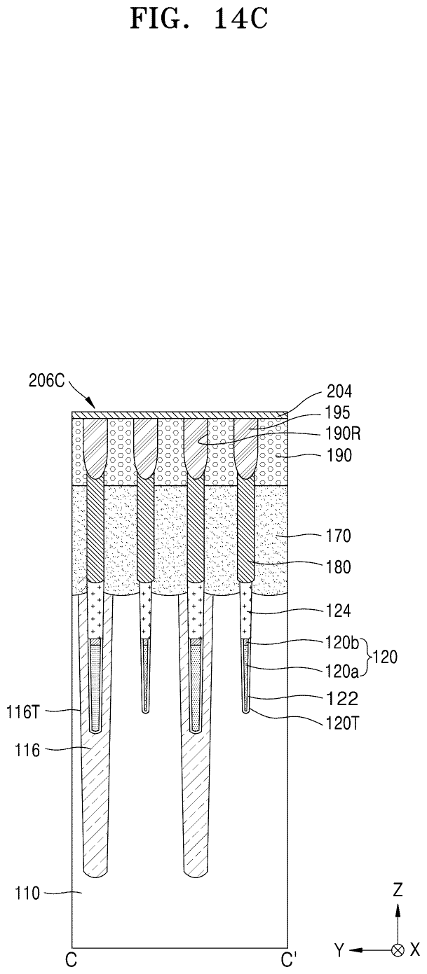

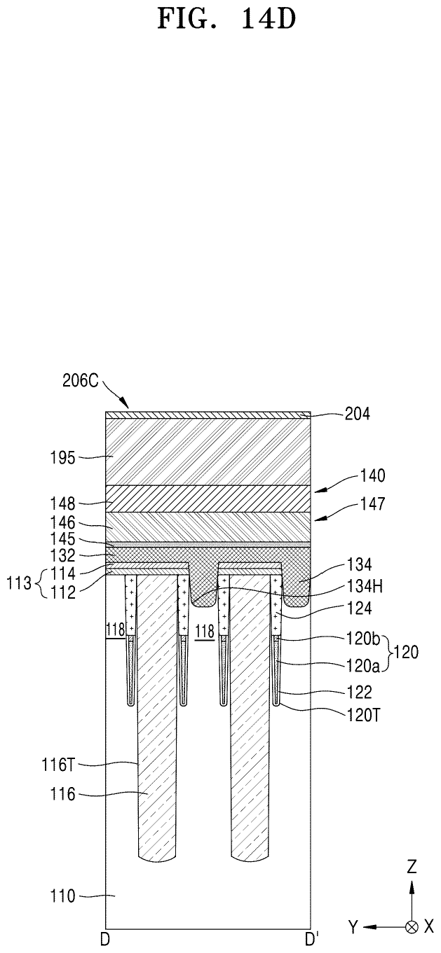

Referring to FIGS. 14A to 14D together, the landing pads 190 and the portion of the filling insulating layer 195 that are not covered by the lower etch stop layer 202 and the upper etch stop layer 204 that covers the lower etch stop layer 202 together are formed, thereby forming an etch stop layer 206 including a stack structure, the stack structure including the lower etch stop layer 202 and the upper etch stop layer 204 on the lower etch stop layer 202. The upper etch stop layer 204 may include a material having etching characteristics that are different from those of silicon oxide and silicon nitride. For example, the upper etch stop layer 204 may include SiBN, SiCN, SiC, SiON, SiCO, SiCON, SiBC, SiBON, SiBCO, SiBCN, or SiBCON. The upper etch stop layer 204 and the lower etch stop layer 202 may include a different material from that of the filling insulating layer 195. The upper etch stop layer 204 and the lower etch stop layer 202 may include the same material. That is, the etch stop layer 206 may include a different material from that of the filling insulating layer 195 and may include SiBN, SiCN, SiC, SiON, SiCO, SiCON, SiBC, SiBON, SiBCO, SiBCN, or SiBCON.

The etch stop layer 206 may include an internal stop layer 206C and a peripheral stop layer 206P. The peripheral stop layer 206P may surround the internal stop layer 206C. The internal stop layer 206C is a portion formed only by a portion of the upper etch stop layer 204 in the etch stop layer 206, and the peripheral stop layer 206P is a portion in which other portions of the lower etch stop layer 206 and the upper etch stop layer 204 form a stack structure. The peripheral stop layer 206P may have an interface between the upper etch stop layer 204 and the lower etch stop layer 202. The portion of the upper etch stop layer 204 included in the internal stop layer 206C and the other portion of the upper etch stop layer 204 included in the peripheral stop layer 206P may form a single body. The internal stop layer 206C may cover a portion of the memory cell region (CR in FIG. 2), and the peripheral stop layer 206P may cover the remaining portion of the memory cell region CR and the peripheral region (PR in FIG. 2). For example, the peripheral stop layer 206P may cover an edge region, which is a portion of the memory cell region CR adjacent to the peripheral region PR, and the peripheral region PR, and the internal stop layer 206C may cover an inner region surrounded by the edge region of the memory cell region CR.

The peripheral stop layer 206P may cover some of the landing pads 190 adjacent to the peripheral region PR, and the internal stop layer 206C may cover the remainder of the landing pads 190. For example, the peripheral stop layer 206P may be formed to cover the landing pads 190 adjacent to each of the four edges of the memory cell region CR, which is the boundary between the peripheral region PR and the memory cell region CR in the landing pads 190, and arranged to form at least one row along each of the four edges, and the internal stop layer 206C may be formed to cover the remaining landing pads 190.

The internal stop layer 206C may have a first thickness T1, and the peripheral stop layer 206P may have a second thickness T2, the second thickness T2 being greater than the first thickness T1. The upper etch stop layer 204 may have the first thickness T1. A thickness of the lower etch stop layer 202 may be a difference between the second thickness T2 and the first thickness T1. For example, the first thickness T1 may be about 30 Å to about 50 Å, and the second thickness T2 may be about 90 Å to about 120 Å. In some embodiments, the first thickness T1 may be less than or equal to 50 Å, and the second thickness T2 may be greater than or equal to 100 Å. For example, each of the lower etch stop layer 202 and the upper etch stop layer 204 may be formed to have a thickness of about 50 Å, the internal stop layer 206C may have a thickness of about 50 Å, and the peripheral stop layer 206P may have a thickness of about 100 Å.

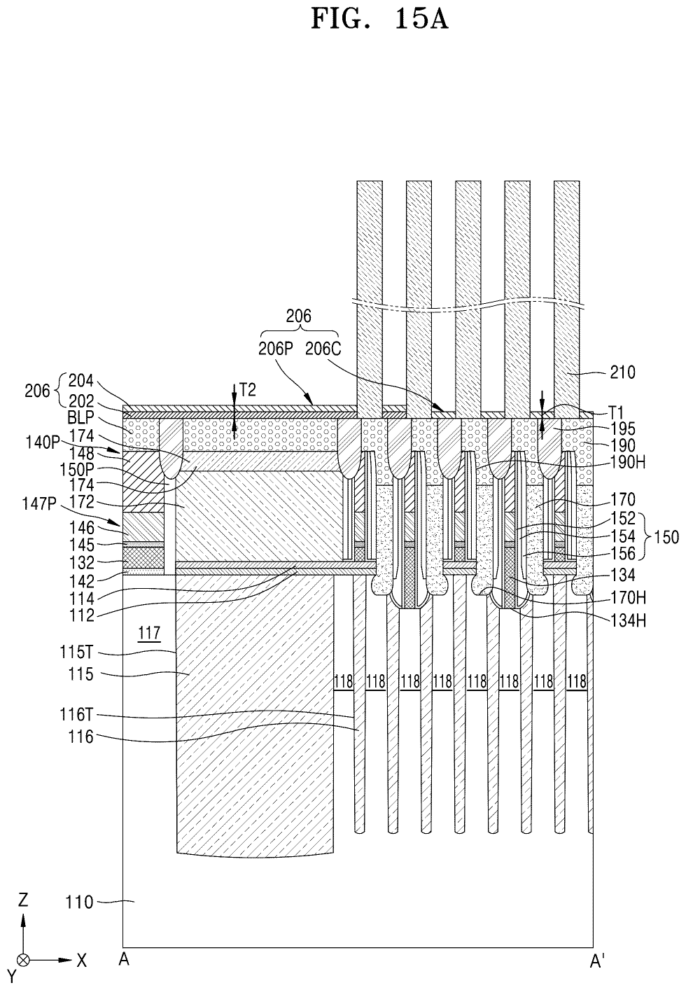

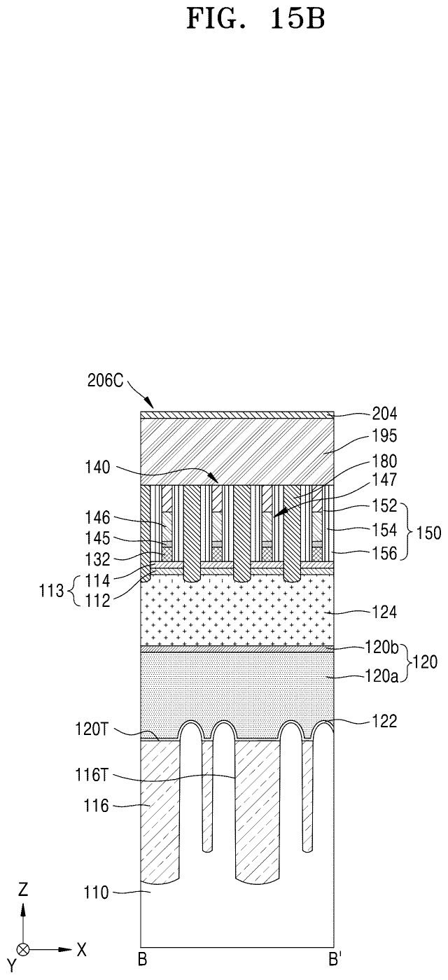

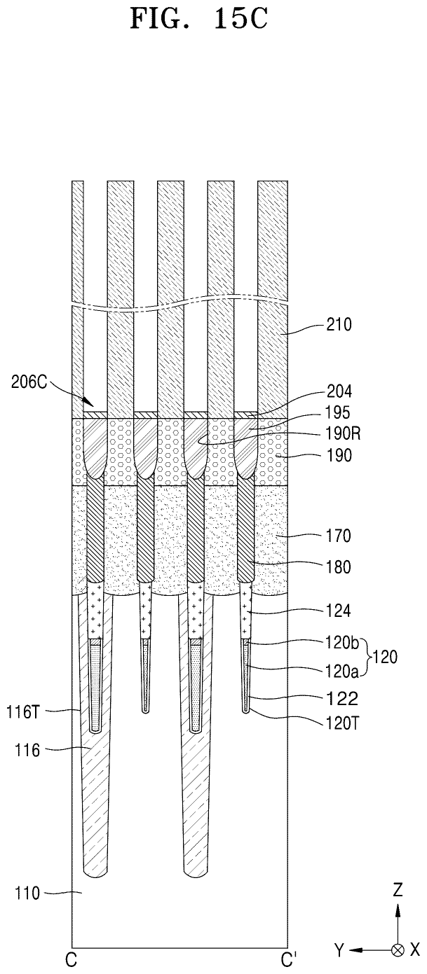

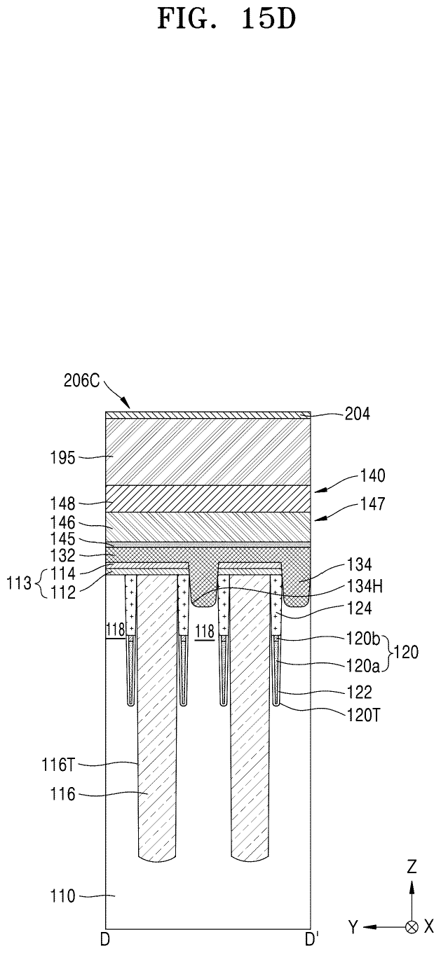

Referring to FIGS. 15A to 15D together, a plurality of lower electrodes 210 that penetrate the etch stop layer 206 to be in contact with the landing pads 190 and extend upward in the vertical direction (the Z direction) are formed. The lower electrodes 210 may be electrically connected to the landing pads 190, respectively. For example, after a mold layer is formed on the etch stop layer 206, a plurality of mold through-holes may be formed through the mold layer to expose the etch stop layer 206 on each bottom surface thereof, and then portions of the etch stop layer 206 exposed on the bottom surfaces of the mold through-holes may be removed to expose the landing pads 190. The lower electrodes 210 that fill the mold through-holes may be formed, and the mold layer may then be removed. The lower electrodes 210 may form the storage nodes SN as illustrated in FIG. 2.

Each of the lower electrodes 210 may have a pillar shape, i.e., a column shape with the interior filled to have a circular horizontal cross-section, but embodiments are not limited thereto. In some embodiments, each of the lower electrodes 210 may have a cylindrical shape with a closed lower portion. In some embodiments, the lower electrodes 210 may be arranged in a honeycomb shape in a zigzag manner with respect to the first horizontal direction (the X direction) or the second horizontal direction (the Y direction). In some other embodiments, the lower electrodes 210 may be arranged in a matrix form in a row in each of the first horizontal direction (the X direction) and the second horizontal direction (the Y direction). For example, the lower electrodes 210 may include a metal, such as silicon, tungsten or copper doped with impurities, or a conductive metal compound, such as titanium nitride. In some embodiments, the lower electrodes 210 may include titanium nitride. In some embodiments, at least one support pattern in contact with sidewalls of the lower electrodes 210 may be further formed. For example, a plurality of support patterns contacting sidewalls of the lower electrodes 210 and located at different vertical levels may be further formed.

Some of the lower electrodes 210 may be formed to pass through the peripheral stop layer 206P, and the remainder may be formed to penetrate the internal stop layer 206C. In some embodiments, some of the lower electrodes 210 adjacent to the peripheral region (PR in FIG. 2) may be formed to penetrate the peripheral stop layer 206P, and the remainder may be formed to penetrate the internal stop layer 206C. For example, among the lower electrodes 210, the lower electrodes 210 adjacent to each of the four edges of the memory cell region CR, which is the boundary between the peripheral region PR and the memory cell region (CR in FIG. 2), and arranged to form at least one row along each of the four edges may be formed to penetrate the peripheral stop layer 206P, and the other lower electrodes 210 may be formed to penetrate the internal stop layer 206C.

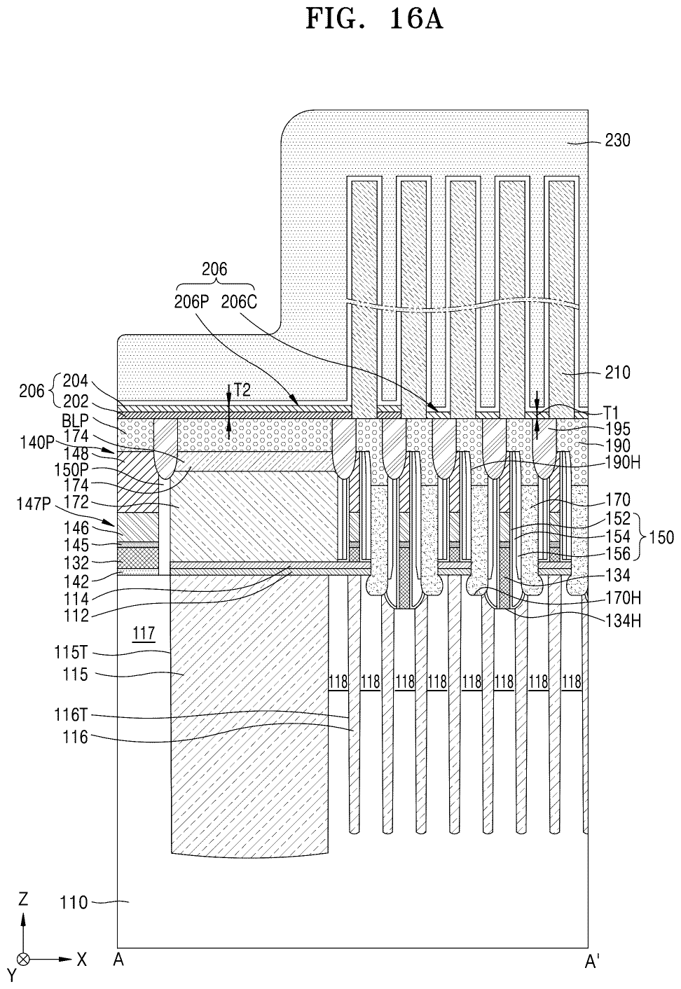

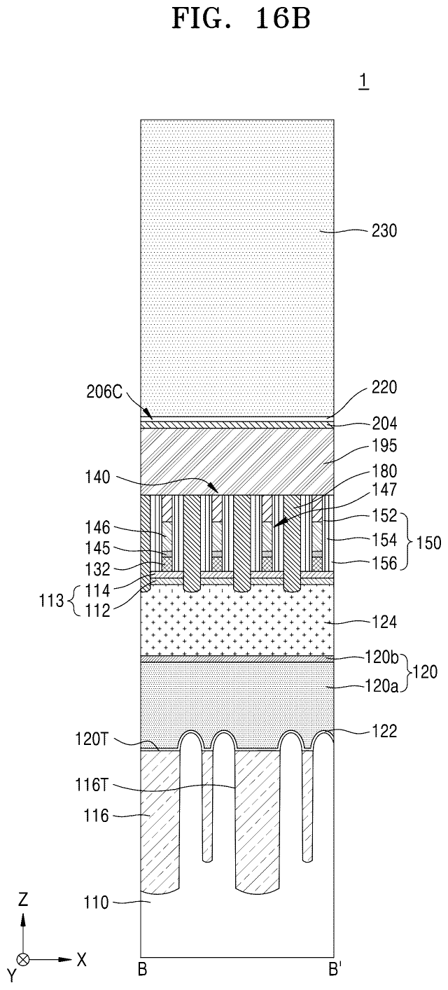

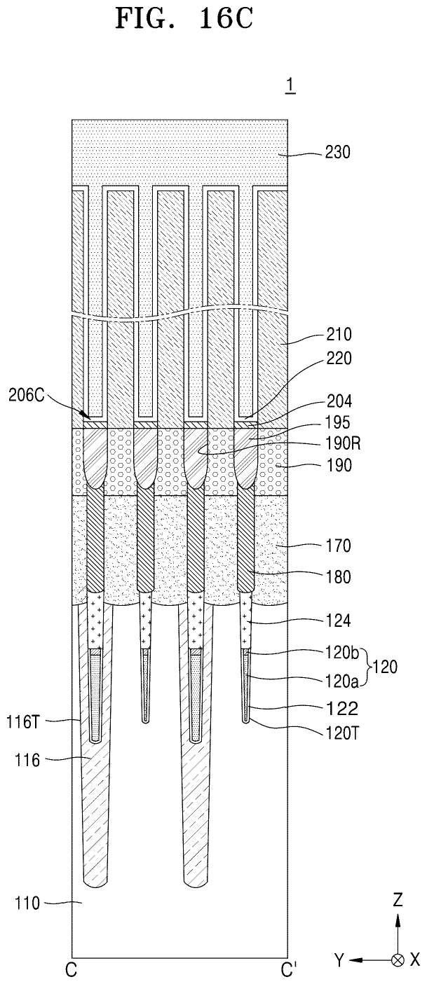

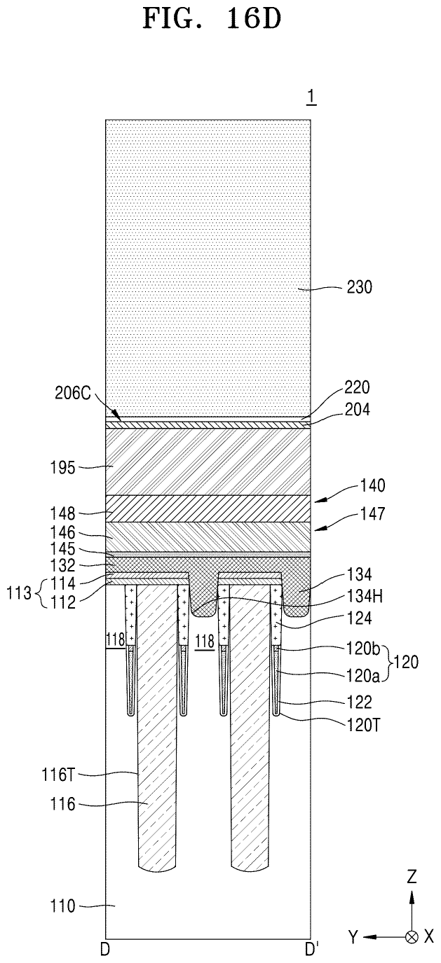

Referring to FIGS. 16A to 16D together, a capacitor dielectric layer 220 and an upper electrode 230 are sequentially formed on the lower electrodes 210. The lower electrodes 210, the capacitor dielectric layers 220, and the upper electrodes 230 may form a plurality of capacitor structures. The capacitor dielectric layer 220 may be formed to conformally cover the surfaces of the lower electrodes 210. The upper electrode 230 may be formed to cover the lower electrodes 210 with the capacitor dielectric layer 220 therebetween.

For example, the capacitor dielectric layer 220 may be formed to have a thickness of about 40 Å to about 70 Å and cover the surfaces of the lower electrodes 210. The capacitor dielectric layer 220 may include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, or combinations thereof.

The upper electrode 230 may include, for example, a semiconductor material, such as doped polysilicon, doped poly-SiGe (polycrystalline silicon germanium), a metallic material, such as W, Ru, Pt, Ir, V, Mo, Ta, Nb, In, TiN, VN, MoN, TaN, NbN, InN, RuO, PtO, IrO, TiO, VO, MoO, TaO, NbO, InO, SRO (SrRuO), BSRO ((Ba,Sr)RuO), CRO (CaRuO), BaRuO, La (Sr,Co)O, or combinations thereof. In some embodiments, the upper electrode 230 may include a metallic material, such as W or Ru. In some other embodiments, the upper electrode 230 may have a stack structure including a semiconductor material and a metallic material. For example, the upper electrode 230 may have a stack structure including at least two layers including a metal-based material and a semiconductor material covering the metal-based material or may have a stack structure including at least three layers including a semiconductor material, a metal-based material covering the semiconductor material, and a semiconductor material covering the metal-based material.

A portion of the upper electrode 230 covering at least a portion of the peripheral region (PR of FIG. 2) and a portion of the capacitor dielectric layer 220 may be removed. In some embodiments, each of the capacitor dielectric layer 220 and the upper electrode 230 may be formed integrally to cover the lower electrodes 210 together within a certain region, for example, one memory cell region (CR of FIG. 2). In some embodiments, the capacitor dielectric layer 220 may be formed to cover both the memory cell region CR and the peripheral region PR.

Referring to FIGS. 17A to 17D together, a cover insulating layer 260 covering the upper electrode 230 is formed. In some embodiments, a lower surface of the cover insulating layer 260 may be in direct contact with an upper surface of the upper electrode 230. The cover insulating layer 260 may include, for example, silicon oxide. For example, the cover insulating layer 260 may include an oxide film or an ultra low K (ULK) film. The oxide film may be formed by any one film selected from among borophosphosilicate glass (BPSG), phosphosilicate glass (PSG), borosilicate glass (BSG), un-doped silicate glass (USG), tetra ethyl ortho silicate (TEOS), or high density plasma (HDP) films. The ULK film may include any one film selected from among a SiOC film and a SiCOH film having an ultra-low dielectric constant K of, for example, 2.2 to 2.4.

A portion of the cover insulating layer 260 is removed to form a plurality of interconnection contact holes MCH. An upper electrode 230 or a logic bit line BLP may be exposed at a bottom surface of each of the interconnection contact holes MCH. The interconnection contact hole MCH may extend through the cover insulating layer 260 to the upper electrode 230. In some embodiments, the interconnection contact hole MCH may extend into the upper electrode 230 or the logic bit line BLP. In some embodiments, the logic active region 117 or the gate line 147P may be exposed at the bottom surface of each of some of the interconnection contact holes MCH.

An interconnection contact plug 310 is formed to fill the interconnection contact hole MCH. The interconnection contact plug 310 may be in contact with the upper electrode 230 or the logic bit line BLP. In some embodiments, the interconnection contact plug 310 may extend into the upper electrode 230 or the logic bit line BLP. Each of the interconnection contact hole MCH and the interconnection contact plug 310 may have a tapered shape having a horizontal width increasing, while extending from the bottom to the top in the vertical direction (the Z direction). Among the interconnection contact plugs 310, the interconnection contact plug 310 in contact with the upper electrode 230 may be referred to as a first interconnection contact plug MC1, and the interconnection contact plug 310 in contact with the logic bit line BLP may be referred to as a second interconnection contact plug MC2.

The interconnection contact plug 310 may include an interconnection contact barrier layer 312 and an interconnection contact filling layer 314. The interconnection contact barrier layer 312 may be formed to conformally cover the internal surface, i.e., the inner sidewall and the bottom surface, of the interconnection contact hole MCH, and the interconnection contact filling layer 314 may be formed to cover the interconnection contact barrier layer 312 and fill the interconnection contact hole MCH. For example, the interconnection contact barrier layer 312 may include Ti, Ta, TiN, TaN, etc. For example, the interconnection contact filling layer 314 may include a metal, such as W.

An interconnection line 320 connected to the interconnection contact plug 310 may be formed on the cover insulating layer 260 on which the interconnection contact plug 310 is formed to form the semiconductor memory device 1. A plurality of interconnection lines 320 may include metals, such as Al, Cu, W, etc., for example.

The semiconductor memory device 1 includes the substrate 110 having the active regions 118, the gate dielectric films 122 sequentially formed inside a plurality of word line trenches 120T crossing the active regions 118 within the substrate 110, the word lines 120, and the buried insulating films 124, the insulating structure 113 covering the device isolation film 116, the active regions 118, and the buried insulating films 124, the bit line structures 140 on the insulating structure 113, the insulating spacer structures 150 covering both sidewalls of the bit line structures 140, the gate line structures 140P on the logic active regions 117, the gate insulating spacers 150P covering both sidewalls of the gate line structures 140P, the logic bit lines BLP on the gate line structures 140P, the buried contacts 170 filling a lower portion of a space defined by the insulating fences 180 and the insulating spacer structures 150 and connected to the active regions 118, the landing pads 190 filling an upper portion and extending to an upper portion of the bit line structure 140, the etch stop layer 206 disposed on the logic bit lines BLP and the landing pads 190, the capacitor structures including the lower electrodes 210 connected to the landing pads 190 through the etch stop layer 206, the capacitor dielectric layer 220, and the upper electrode 230, the interconnection contact plug 310 connected to the upper electrode 230, and the interconnection line 320 connected to the interconnection contact plug 310.

The etch stop layer 206 may be formed to be disposed on the landing pads 190, the logic bit lines BLP, and the filling insulating layer 195. The etch stop layer 206 may include an internal stop layer 206C having the first thickness T1 and a peripheral stop layer 206P having the second thickness T2, the second thickness T2 being greater than the first thickness T1. The internal stop layer 206C may cover a portion of the memory cell region (CR in FIG. 2), and the peripheral stop layer 206P may cover another portion of the memory cell region CR and the peripheral region (PR in FIG. 2). Each of the lower electrodes 210, except for some adjacent to the peripheral region PR, may be connected to the landing pad 190 by penetrating the internal stop layer 206C having the first thickness T1, which is relatively thin. Some of the lower electrodes 210 adjacent to the peripheral region PR may each be connected to the landing pad 190 by penetrating the peripheral stop layer 206P having the second thickness T2 which is relatively thick. The peripheral region may be covered by the peripheral stop layer 206P having the second thickness T2 which is relatively thick. The lower electrodes 210 may include a plurality of real lower electrodes and a plurality of dummy lower electrodes, each of the real lower electrodes may be connected to the landing pad 190 by penetrating the internal stop layer 206C, and at least some of the dummy lower electrodes may be connected to the landing pad 190 by penetrating the peripheral stop layer 206P.

Among the lower electrodes 210, the real lower electrodes are connected to the landing pads 190 by penetrating the internal stop layer 206C having the first thickness T1, which is relatively thin, so that a NOT OPEN defect, which is a defect in which the lower electrodes 210 do not penetrate the etch stop layer 206 and are not connected to the landing pad 190, may not occur. In addition, among the lower electrodes 210, at least some of the dummy lower electrodes penetrate the peripheral stop layer 206P having second thickness T2 which is relatively thick, lower portions of at least some of the dummy lower electrodes may be supported by the peripheral stop layer 206P which is relatively thick, so that collapse/leaning defects may not occur in the lower electrodes 210. Also, because the peripheral region PR is covered by the peripheral stop layer 206P which is relatively thick, the occurrence of damage to the peripheral stop layer 206P in the peripheral region PR and thus damage to the structure below the peripheral stop layer 206P, for example, damage to the gate line 147P, in the process of forming the lower electrodes 210 may be prevented. Therefore, the electrical/structural reliability of the semiconductor memory device 1 may be improved.

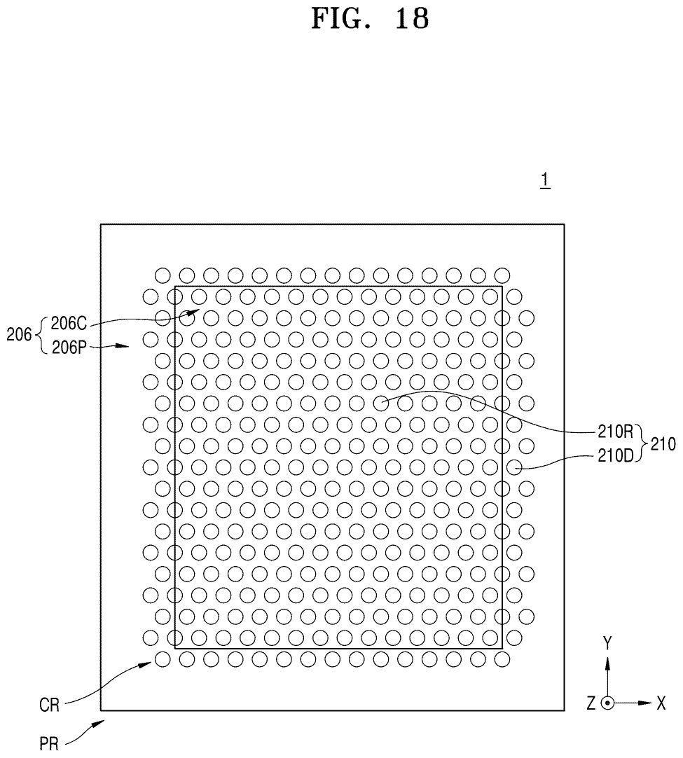

FIG. 18 is a schematic planar layout diagram of the main components included in the semiconductor memory device 1 according to embodiments.

Referring to FIG. 18, the semiconductor memory device 1 includes the memory cell region CR and the peripheral region PR surrounding the memory cell region CR. The lower electrodes 210 may be arranged in the memory cell region CR. The lower electrodes 210 may be arranged in a honeycomb shape in a zigzag manner with respect to the first horizontal direction (the X direction) or the second horizontal direction (the Y direction). In some other embodiments, the lower electrodes 210 may be arranged in a matrix form in a row in each of the first horizontal direction (the X direction) and the second horizontal direction (the Y direction).

The lower electrodes 210 may include a plurality of real lower electrodes 210R and a plurality of dummy lower electrodes 210D. In a planar view, the dummy lower electrodes 210D may be arranged to surround the real lower electrodes 210R. The real lower electrodes 210R among the lower electrodes 210 are lower electrodes 210 that function as memory cells of the semiconductor memory device 1, and the dummy lower electrodes 210D among the lower electrodes 210 are lower electrodes 210 that do not function as memory cells of the semiconductor memory device 1. The real lower electrodes 210R may have substantially the same structure as the dummy lower electrodes 210D, and memory cells that include the real lower electrodes 210R and function may also have substantially the same structure as memory cells (dummy memory cells) that include the dummy lower electrodes 210D and do not function. The dummy lower electrodes 210D may be formed together with the real lower electrodes 210R in order to secure structural reliability and operational reliability of the semiconductor memory device 1 or to secure process stability during the manufacturing process of the semiconductor memory device 1.

The etch stop layer 206 may include the internal stop layer 206C and the peripheral stop layer 206P. The internal stop layer 206C may cover a portion of the memory cell region CR, and the peripheral stop layer 206P may cover another portion of the memory cell region CR and the peripheral region PR. For example, the peripheral stop layer 206P may cover an edge region, which is a portion of the memory cell region CR adjacent to the peripheral region PR, and the peripheral region PR, and the internal stop layer 206C may cover an inner region surrounded by the edge region of the memory cell region CR.

The dummy lower electrodes 210D may be disposed in a portion of the memory cell region CR adjacent to the peripheral region PR. In a planar view, the dummy lower electrodes 210D may be arranged to surround a plurality of real lower electrodes 210R. At least two lower electrodes 210 arranged inwardly from the edge of the memory cell region CR in each of the first horizontal direction (the X direction) and the second horizontal direction (the Y direction) may be the dummy lower electrodes 210D.

The real lower electrodes 210R may be arranged to penetrate the internal stop layer 206C. Some of the dummy lower electrodes 210D may be arranged to penetrate the internal stop layer 206C, and others may be arranged to penetrate the peripheral stop layer 206P. For example, some of the dummy lower electrodes 210D adjacent to the real lower electrodes 210R may be arranged to penetrate the internal stop layer 206C, and other some of the dummy lower electrodes adjacent to the peripheral region PR may be arranged to penetrate the peripheral stop layer 206P. At least one dummy lower electrode 210D arranged inwardly from the edge of the memory cell region CR in each of the first horizontal direction (the X direction) and the second horizontal direction (the Y direction) may be arranged to penetrate the peripheral stop layer 206P, and at least one dummy lower electrode 210D arranged inwardly from the real lower electrodes 210R in each of the first horizontal direction (the X direction) and the second horizontal direction (the Y direction) may be arranged to penetrate the internal stop layer 206C.

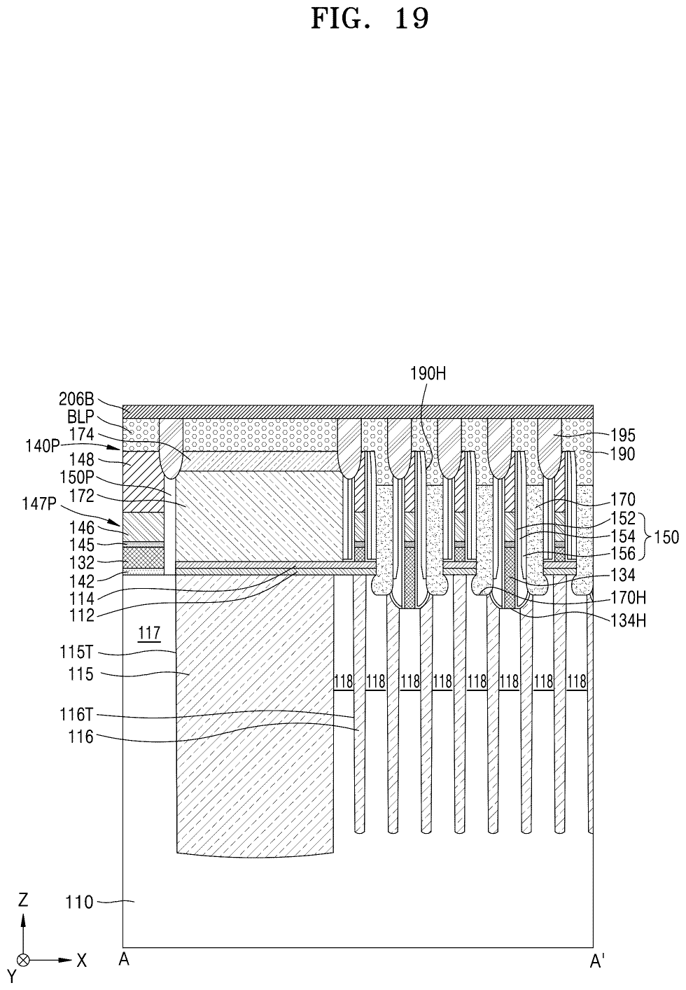

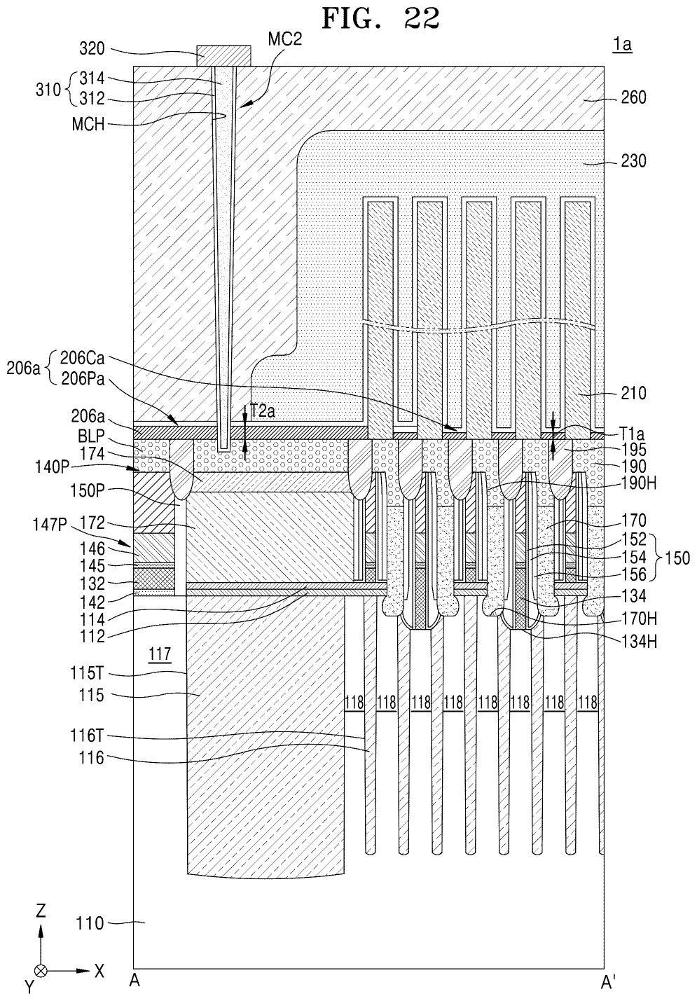

FIGS. 19 to 21 are cross-sectional views illustrating a method of manufacturing the semiconductor memory device 1 according to embodiments, and FIG. 22 is a cross-sectional view illustrating the semiconductor memory device according to embodiments. In detail, FIGS. 19, 20, 21, and 22 are cross-sectional views taken along a position corresponding to line A-A′ of FIG. 2.

Referring to FIG. 19, in a resultant image shown in FIGS. 9A to 9D, that is, an etch stop material layer 206B covering the landing pads 190, the logic bit lines BLP, and the filling insulating layer 195 is formed. The etch stop material layer 206B may include a material having etching characteristics that are different from those of silicon oxide and silicon nitride. For example, the etch stop material layer 206B may include SiBN, SiCN, SiC, SiON, SiCO, SiCON, SiBC, SiBON, SiBCO, SiBCN, or SiBCON.

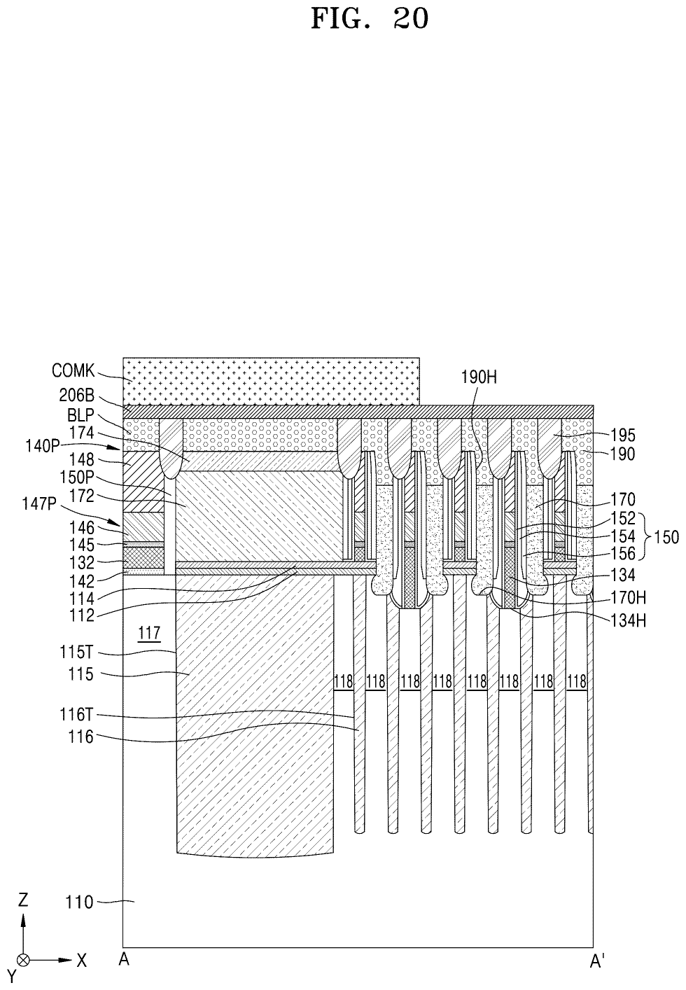

Referring to FIG. 20, the cell open mask pattern COMK is formed on the etch stop material layer 206B. The cell open mask pattern COMK may be formed to cover the peripheral region (PR in FIG. 2) but not cover a portion of the memory cell region (CR in FIG. 2). The cell open mask pattern COMK may be formed to cover a portion of the memory cell region CR adjacent to the peripheral region PR and the peripheral region PR. For example, the cell open mask pattern COMK may be formed to cover the edge region of the memory cell region CR but not cover an inner region surrounded by the edge region of the memory cell region CR.

The cell open mask pattern COMK may be formed to overlap some of the landing pads 190 adjacent to the peripheral region PR in the vertical direction (the Z direction) but not overlap the remainder of the landing pads 190. For example, the cell open mask pattern COMK may be formed to overlap the landing pads 190 adjacent to each of four edges of the memory cell region CR, which is the boundary between the peripheral region PR and the memory cell region CR, among the landing pads 190 and arranged to form at least one row along each of the four edges of the memory cell region CR.

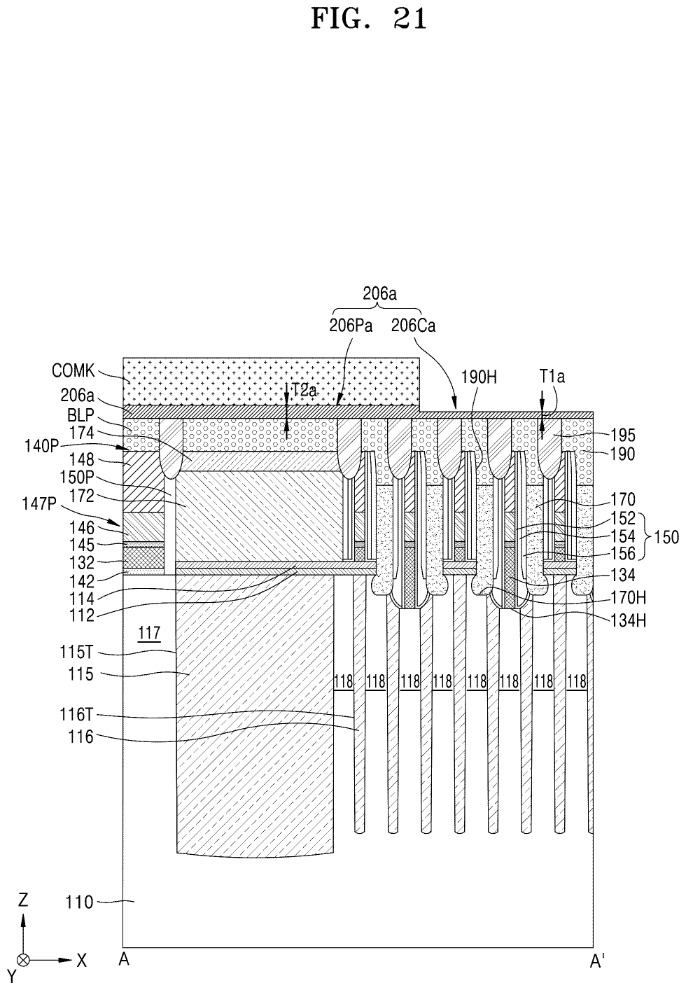

Referring to FIGS. 20 and 21 together, an upper portion of a portion of the etch stop material layer 206B that is not covered by a cell open mask pattern COMK is removed to form an etch stop layer 206a. After the etch stop layer 206a is formed, the cell open mask pattern COMK is removed.

The etch stop layer 206a may include an internal stop layer 206Ca and a peripheral stop layer 206Pa. In a planar view, the peripheral stop layer 206Pa may surround the internal stop layer 206Ca. The internal stop layer 206Ca may cover a portion of the memory cell region (CR in FIG. 2), and the peripheral stop layer 206Pa may cover another portion of the memory cell region CR and the peripheral region (PR in FIG. 2). For example, the peripheral stop layer 206Pa may cover an edge region, which is a portion of the memory cell region CR adjacent to the peripheral region PR, and the peripheral region PR, and the internal stop layer 206Ca may cover an inner region surrounded by the edge region of the memory cell region CR.

The peripheral stop layer 206P of the etch stop layer 206 shown in FIGS. 14A to 14D is formed as a stack structure including the lower etch stop layer 202 and the upper etch stop layer 204 on the lower etch stop layer 202, and thus has an interface between the upper etch stop layer 204 and the lower etch stop layer 202 within the peripheral stop layer 206P, while the peripheral stop layer 206Pa of the etch stop layer 206a may be formed as a single-layer structure, and thus may not have an interface within the peripheral stop layer 206Pa. The internal stop layer 206Ca and the peripheral stop layer 206Pa included in the etch stop layer 206a may have a single layer structure and may form an integral body.

The peripheral stop layer 206Pa may cover some of the landing pads 190 adjacent to the peripheral region PR, and the internal stop layer 206Ca may cover the remainder of the landing pads 190. For example, the peripheral stop layer 206Pa may be formed to cover the landing pads 190 that are adjacent to each of the four edges of the memory cell region CR, which is the boundary between the peripheral region PR and the memory cell region CR, among the landing pads 190, and are arranged to form at least one row along each of the four edges, and the internal stop layer 206Ca may be formed to cover the remaining landing pads 190.

The internal stop layer 206Ca may have a first thickness T1a, and the peripheral stop layer 206Pa may have a second thickness T2a greater than the first thickness T1a. For example, the first thickness T1a may be about 30 Å to about 50 Å, and the second thickness T2a may be about 90 Å to about 120 Å. In some embodiments, the first thickness T1a may be less than or equal to 50 Å, and the second thickness T2a may be greater than or equal to 100 Å.

Referring to FIG. 22 together with FIGS. 15A to 17D, the lower electrodes 210 penetrating the etch stop layer 206a, the capacitor dielectric layer 220, the upper electrode 230, the cover insulating layer 260, the interconnection contact plug 310, and the interconnection line 320 is formed, thereby forming a semiconductor memory device 1a. Instead of the etch stop layer 206 included in the semiconductor memory device 1 shown in FIGS. 17A to 17D, the semiconductor memory device 1a may include the etch stop layer 206a.

The semiconductor memory device 1a according to embodiments includes the etch stop layer 206a including the internal stop layer 206Ca having the first thickness T1 which is relatively thin and the peripheral stop layer 206Pa having the second thickness T2 which is relatively thick, so that electrical/structural reliability may be improved.

While aspects of embodiments have been particularly shown and described, it will be understood that various changes in form and details may be made therein without departing from the spirit and scope of the following claims.

What is claimed is:

1. A semiconductor memory device comprising:
a substrate in which a plurality of active regions are defined by a device isolation film in a memory cell region and a logic active region is defined by a logic device isolation film in a peripheral region;
a plurality of landing pads connected to the plurality of active regions in the memory cell region, on the substrate;
an etch stop layer comprising an internal stop layer having a first thickness and a peripheral stop layer having a second thickness greater than the first thickness, wherein the etch stop layer is provided on the memory cell region and the peripheral region;
a plurality of lower electrodes penetrating the etch stop layer and connected to the plurality of landing pads;
a capacitor dielectric layer covering the plurality of lower electrodes; and
an upper electrode covering the capacitor dielectric layer,
wherein a first group of the plurality of lower electrodes penetrate the peripheral stop layer, and a second group of the plurality of lower electrodes penetrate the internal stop layer and are connected to the plurality of landing pads.

2. The semiconductor memory device of claim 1, wherein the internal stop layer covers a portion of the memory cell region, and
wherein the peripheral stop layer covers another portion of the memory cell region and the peripheral region.

3. The semiconductor memory device of claim 2, wherein the peripheral stop layer covers the peripheral region and an edge region that is a portion of the memory cell region adjacent to the peripheral region, and
wherein the internal stop layer covers an inner region surrounded by the edge region of the memory cell region.

4. The semiconductor memory device of claim 1, wherein the etch stop layer is formed as a stack structure comprising a lower etch stop layer and an upper etch stop layer, and
wherein the peripheral stop layer comprises a portion of the upper etch stop layer and the lower etch stop layer, and the internal stop layer comprises another portion of the upper etch stop layer.

5. The semiconductor memory device of claim 4, wherein the peripheral stop layer of the etch stop layer has an interface between the lower etch stop layer and a portion of the etch stop layer.

6. The semiconductor memory device of claim 1, further comprising a filling insulating layer separating the plurality of landing pads from each other,
wherein the etch stop layer comprises a different material from a material of the filling insulating layer, and covers the memory cell region and the peripheral region on the plurality of landing pads and the filling insulating layer.

7. The semiconductor memory device of claim 1, wherein the plurality of lower electrodes comprise a plurality of real lower electrodes and a plurality of dummy lower electrodes provided around the plurality of real lower electrodes, and
wherein each of the plurality of real lower electrodes penetrates the internal stop layer.

8. The semiconductor memory device of claim 7, wherein a first group of the plurality of dummy lower electrodes penetrate the internal stop layer, and a second group of the plurality of dummy lower electrodes penetrate the peripheral stop layer.

9. The semiconductor memory device of claim 8, wherein at least two lower electrodes, among the plurality of lower electrodes, provided inwardly from an edge of the memory cell region in a first horizontal direction and a second horizontal direction orthogonal to the first horizontal direction are the plurality of dummy lower electrodes, and
wherein at least one dummy lower electrode, among the plurality of dummy lower electrodes, provided inwardly from the edge of the memory cell region in each of the first horizontal direction and the second horizontal direction penetrates the peripheral stop layer.

10. The semiconductor memory device of claim 1, wherein the internal stop layer and the peripheral stop layer are integrally formed.

11. A semiconductor memory device comprising:
a substrate in which a plurality of active regions are defined by a device isolation film in a memory cell region and a plurality of logic active regions are defined by a logic device isolation film in a peripheral region;
a plurality of word lines extending in a first horizontal direction across the plurality of active regions in the memory cell region;
a plurality of bit lines on the plurality of active regions and extending in a second horizontal direction orthogonal to the first horizontal direction;
a plurality of buried contacts filling a lower portion of a space between the plurality of bit lines and connected to the plurality of active regions;
a plurality of landing pads filling an upper portion of the space between the plurality of bit lines, extending over the plurality of bit lines, and separated from each other by a filling insulating layer;
a gate line on the plurality of logic active regions;
a plurality of logic bit lines on the gate line;
an etch stop layer comprising an internal stop layer having a first thickness and a peripheral stop layer having a second thickness greater than the first thickness, wherein the etch stop layer is provided on the memory cell region and the peripheral region, and wherein the etch stop layer overlaps the plurality of landing pads and the plurality of logic bit lines;
a plurality of lower electrodes comprising a plurality of real lower electrodes and a plurality of dummy lower electrodes provided around the plurality of real lower electrodes, wherein the plurality of lower electrodes penetrate the etch stop layer and are connected to the plurality of landing pads;
a capacitor dielectric layer covering the plurality of lower electrodes; and
an upper electrode covering the capacitor dielectric layer,
wherein a first group of the plurality of dummy lower electrodes penetrate the internal stop layer, and a second group of the plurality of dummy lower electrodes penetrate the peripheral stop layer.

12. The semiconductor memory device of claim 11, wherein each of the plurality of real lower electrodes penetrates the internal stop layer.

13. The semiconductor memory device of claim 11, wherein the peripheral stop layer surrounds the internal stop layer.

14. The semiconductor memory device of claim 11, wherein the first group of the plurality of dummy lower electrodes is adjacent to the plurality of real lower electrodes, and the second group of the plurality of dummy lower electrodes is adjacent to the peripheral region.

15. The semiconductor memory device of claim 14, wherein the plurality of dummy lower electrodes comprise:
at least two lower electrodes provided inwardly from an edge of the memory cell region in each of the first horizontal direction and the second horizontal direction; and
at least one additional lower electrode penetrating the peripheral stop layer and provided inwardly from the edge of the memory cell region in each of the first horizontal direction and the second horizontal direction.

16. The semiconductor memory device of claim 11, wherein the etch stop layer comprises a different material from a material of the filling insulating layer.

17. The semiconductor memory device of claim 11, wherein the etch stop layer is formed as a stack structure comprising a lower etch stop layer and an upper etch stop layer comprising a common material and having an interface therebetween, and
wherein the peripheral stop layer comprises a portion of the upper etch stop layer and the lower etch stop layer, and the internal stop layer comprises another portion of the upper etch stop layer.

18. A semiconductor memory device comprising:
a substrate in which a plurality of active regions are defined by a device isolation film in a memory cell region and a plurality of logic active regions are defined by a logic device isolation film in a peripheral region;
a gate line on the plurality of logic active regions;
a logic bit line on the gate line;
a plurality of word lines extending in a first horizontal direction across the plurality of active regions;
a plurality of bit lines on the plurality of active regions and extending in a second horizontal direction orthogonal to the first horizontal direction;
a plurality of buried contacts filling a lower portion of a space between the plurality of bit lines and connected to the plurality of active regions;
a plurality of landing pads extending over the plurality of bit lines, while filling an upper portion of the space between the plurality of bit lines, at least some separated from each other by a filling insulating layer being positioned at a vertical level corresponding to a vertical level of the logic bit line;
an etch stop layer covering the memory cell region and the peripheral region, wherein the etch stop layer overlaps the plurality of landing pads, the filling insulating layer, and the plurality of bit lines;
a plurality of lower electrodes comprising a plurality of real lower electrodes and a plurality of dummy lower electrodes provided around the plurality of real lower electrodes, wherein the plurality of lower electrodes penetrate the etch stop layer and are connected to the plurality of landing pads;
a capacitor dielectric layer covering the plurality of lower electrodes;
an upper electrode covering the capacitor dielectric layer;
a cover insulating layer covering the etch stop layer and the upper electrode;
a plurality of interconnection lines on the filling insulating layer;
a first interconnection contact plug penetrating the filling insulating layer and connecting one of the plurality of interconnection lines to the upper electrode; and
a second interconnection contact plug penetrating the filling insulating layer and connecting another one of the plurality of interconnection lines to the logic bit line,
wherein the etch stop layer comprises an internal stop layer having a first thickness and a peripheral stop layer having a second thickness greater than the first thickness, and
wherein a first group of the plurality of dummy lower electrodes and all of the plurality of real lower electrodes penetrate the internal stop layer, and a second group of the plurality of dummy lower electrodes penetrate the peripheral stop layer.

19. The semiconductor memory device of claim 18, wherein the peripheral stop layer surrounds the internal stop layer, and
wherein the first group of the plurality of dummy lower electrodes is adjacent to the plurality of real lower electrodes, and the second group of the plurality of dummy lower electrodes is adjacent to the peripheral region.

20. The semiconductor memory device of claim 18, wherein the etch stop layer comprises SiBN and is a different material from a material of the filling insulating layer.
